(19) United States
(12) Patent Application Publication
(10) Pub. No.: US 2012/0286395 A1
(43) Pub. Date: Nov. 15, 2012

(54) EMBEDDED CAPACITOR DEVICE AND METHODS OF FABRICATION

(76) Inventor: Kevin John Fischer, Hillsboro, OR (US)

(21) Appl. No.: 13/555,402

(22) Filed: Jul. 23, 2012

Related U.S. Application Data
(63) Continuation of application No. 12/397,843, filed on Mar. 4, 2009.

(51) Int. Cl. H01L 29/02; H01L 21/02

(52) U.S. Cl. 257/532; 438/396; 257/E29.002; 257/E21.008

(57) ABSTRACT

Embodiments of the present invention describe a semiconductor device having an embedded capacitor device and methods of fabricating the capacitor device. The capacitor device is formed between the passivation layers above the backend interconnect stack of a substrate. Fabricating the capacitor device between the passivation layers above the backend interconnect stack minimizes any adverse effects the capacitor device might cause to the backend interconnect stack.

### CROSS REFERENCE TO RELATED APPLICATIONS

The present application is a continuation of U.S. patent application Ser. No. 12/397,843, entitled “EMBEDDED CAPACITOR DEVICE AND METHODS OF FABRICATION” filed on Mar. 4, 2009.

### BACKGROUND OF THE INVENTION

1. Field of the Invention

The present invention relates to the field of semiconductor processing and more particularly to a semiconductor device having an embedded capacitor device and its method of fabrication.

2. Discussion of Related Art

Modern integrated circuits, such as microprocessors, use numerous passive components such as resistors and capacitors. In one application, decoupling capacitors are used to reduce undesired noise signals from the power supply. One method of adding decoupling capacitors to the microprocessor is by forming them on the package substrate. However, this method requires electrical routing between the capacitors and microprocessor, which increases thickness and cost of the package substrate. Furthermore, the electrical routing to the capacitors on the package increases inductance.

Decoupling capacitors can also be formed by on-chip techniques. For example, decoupling capacitors such as gate oxide capacitors or finger comb capacitors are formed in the lower metal layers of the backend interconnect stack. However, the capacitance output of gate oxide or finger comb capacitors is limited by high voltage breakdown and layout factors.

FIG. 1 illustrates a semiconductor device with a conventional metal-insulator-metal (MIM) capacitor formed in the backend interconnect stack. The semiconductor device comprises a substrate 10 having a backend interconnect stack 30 formed thereon. The backend interconnect stack 30 comprises multiple levels of metal lines or interconnects 41-43, 51-55, 61, 62, 71-73 that are isolated by multiple layers of interlayer dielectric 31-34. Typically, a MIM capacitor is formed between two layers of interlayer dielectric. In this case, the MIM capacitor 80 is formed in an etch-stop layer 20 between the two layers of interlayer dielectric 31, 32. The MIM capacitor 80 includes a bottom electrode 81, a top electrode 82, and a dielectric layer 83 formed between the bottom and top electrodes 81, 82. The bottom electrode 81 is coupled to interconnect 54, and top electrode 82 is coupled to interconnect 52.

In one application, the interconnect 52 is coupled to a positive supply node V+ (not shown), and the other interconnect 54 is coupled to a negative power supply node V− (not shown). In this case, the MIM capacitor 80 functions as a decoupling capacitor for the power supplies V+ and V−. However, fabricating the MIM capacitor 80 between the layers of interlayer dielectric 31, 32 increases the parasitic capacitance of the neighboring metal lines, for example metal lines 42 and 53. Furthermore, the MIM capacitor 80 also affects backend layout designs by consuming area intended for routing of metal lines.

### BRIEF DESCRIPTION OF THE DRAWINGS

FIG. 1 is a cross-sectional view that illustrates a conventional metal-insulator-metal (MIM) capacitor formed in a backend interconnect stack.

FIG. 2 is a cross-sectional view that illustrates a capacitor device in accordance with one embodiment of the present invention.

FIG. 3 is a top plan view that illustrates the capacitor device in FIG. 2.

FIG. 4 is a cross-sectional view that illustrates a capacitor device in accordance with another embodiment of the present invention.

FIG. 5 is a top plan view that illustrates the capacitor device in FIG. 4.

FIG. 6 is a cross-sectional view that illustrates a capacitor device in accordance with yet another embodiment of the present invention.

FIG. 7 is a top plan view that illustrates the capacitor device in FIG. 6.

FIGS. 8A-8I are cross-sectional views that illustrate the method of forming the embedded capacitor as shown in FIG. 2.

FIGS. 9A-9J are cross-sectional views that illustrate the method of forming the embedded capacitor as shown in FIG. 4.

FIG. 9B′ is a top plan view that illustrates the photoresist mask as shown in FIG. 9B.

FIGS. 10A-10K are cross-sectional views that illustrate the method of forming the embedded capacitor as shown in FIG. 6.

FIG. 10B′ is a top plan view that illustrates the photoresist mask as shown in FIG. 10B.

FIG. 10F′ is a top plan view that illustrates the bottom electrode of the capacitor device in FIG. 10F.

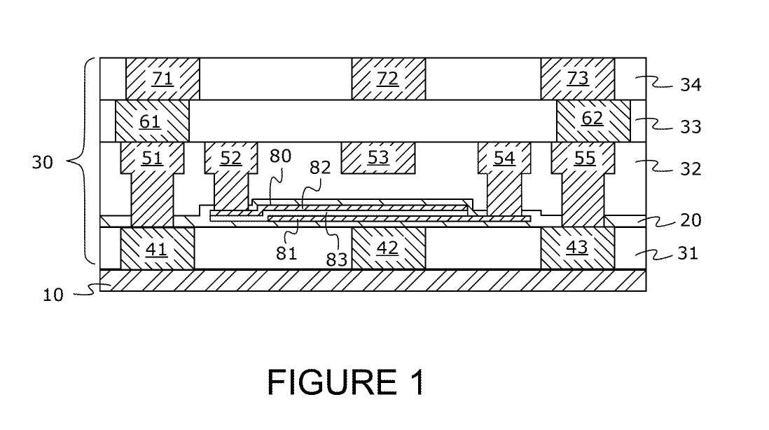

### DETAILED DESCRIPTION OF THE PRESENT INVENTION

In the following description, numerous specific details are set forth in order to provide a thorough understanding of the present invention. In other instances, well known semiconductor processing techniques and features have not been described in particular detail in order not to unnecessarily obscure the present invention.

Embodiments of the present invention describe a semiconductor device having an embedded capacitor device. In an embodiment of the present invention, the semiconductor device comprises a substrate having a backend interconnect stack formed thereon. The backend interconnect stack includes a topmost interlayer dielectric. A bottom passivation layer is formed above the topmost interlayer dielectric. A top passivation layer is formed on the bottom passivation layer. A capacitor device is disposed between the bottom and top passivation layers, wherein the capacitor device comprises a bottom electrode, a top electrode, and a dielectric layer formed between the bottom and top electrodes. Fabricating the capacitor device between the top and bottom passivation layers eliminates any adverse effects the capacitor device might cause to the metal layers in the backend interconnect stack. In one embodiment, the bottom electrode includes a substantially planar bottom plate, and the top electrode includes a substantially planar top plate parallel to the bottom plate. In other embodiments, the bottom and top plates are non-planar. In one embodiment, the bottom electrode includes a corrugated bottom plate, and the top electrode includes a corrugated top plate parallel to the corrugated bottom plate. In yet another embodiment, the bottom electrode includes a waffle-shaped bottom plate, and the top electrode includes a waffle-shaped top plate parallel to the waffle-shaped bottom plate.

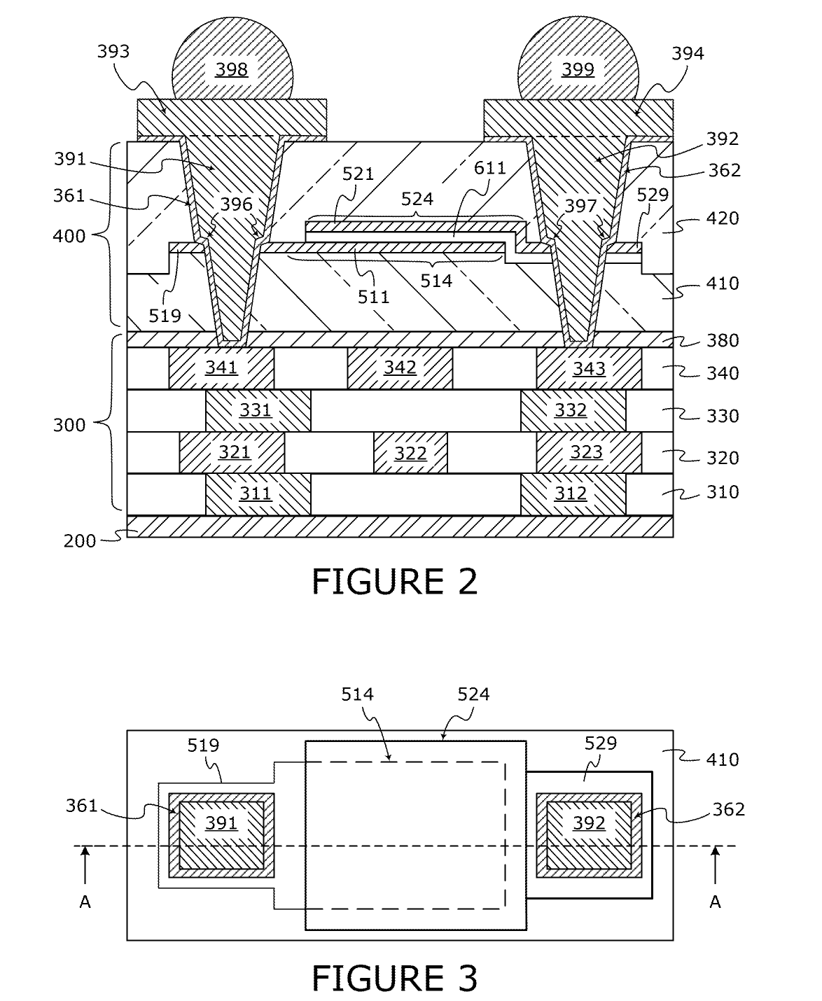

FIG. 2 illustrates a cross-sectional view of a semiconductor device comprising a substrate 200 having a backend interconnect stack 300 formed thereon. In one embodiment, the substrate 200 is made of a semiconductor material such as but not limited to silicon (Si), silicon germanium (SiGe), germanium (Ge), and III-V compound semiconductors. Substrate 200 can be monocrystalline or polycrystalline. In one embodiment, substrate 200 is a semiconductor heterostructure such as but not limited to a silicon-on-insulator (SOI) substrate, or a multi-layered substrate comprising silicon, silicon germanium, germanium, III-V compound semiconductors, and any combinations thereof. The substrate 200 includes a layer of active devices (not shown). Active devices refer to components such as but not limited to transistors, rectifiers, and isolation structures that form part of an integrated circuit. The active devices are coupled together into functional circuits by the backend interconnect stack 300.

The backend interconnect stack 300 comprises multiple levels of metal layers or interconnects 311, 312, 321-323, 331, 332, 341-343 that are isolated from one another by multiple layers of interlayer dielectric 310, 320, 330, 340. In one embodiment of the present invention, the backend interconnect stack 300 comprises four layers of interlayer dielectric 310, 320, 330, 340 as shown in FIG. 2. However, it can be appreciated that the backend interconnect stack 300 is not limited to four layers of interlayer dielectrics but can have greater or lesser than four layers. Interlayer dielectric 310 is the bottommost interlayer dielectric that is formed on the substrate 200. On the other hand, interlayer dielectric 340 is the topmost interlayer dielectric of the interconnect stack 300.

The interlayer dielectrics 310, 320, 330, 340 are made from well known dielectric materials, such as but not limited to silicon dioxide (SiO₂). Each layer of interlayer dielectric 310, 320, 330, 340 is about 0.50 micrometers. The metal layers 311, 312, 321-323, 331, 332, 341-343 are made from metal or metal alloys, such as but not limited to aluminum (Al), titanium (Ti), copper (Cu) and tungsten (W). Etch stop layers can be formed between or within the interlayer dielectrics 310, 320, 330, 340. In an embodiment of the present invention, an etch stop layer 380 is formed on top of the topmost interlayer dielectric 340. In one embodiment, the etch stop layer 380 is made of silicon carbide.

A passivation structure 400 is formed on the backend interconnect stack 300. In an embodiment of the present invention, the passivation structure 400 comprises a bottom passivation layer 410, and a top passivation layer 420 formed above the bottom passivation layer 410. Bottom passivation layer 410 is formed above the backend interconnect stack 300. In one embodiment, the bottom passivation layer 400 is formed on the etch stop layer 380.

Both the bottom and top passivation layers 410, 420 are made of a material that protects the backend interconnect stack 300 and the underlying substrate 200 from moisture or contaminants. In one embodiment, the bottom and top passivation layers 410, 420 are made from a material such as but not limited to oxides or nitrides. For example, the bottom and top passivation layers 410, 420 can be made of silicon dioxide (SiO₂) or silicon nitride (SiN). In a particular embodiment, the bottom passivation layer 410 is made of silicon dioxide and the top passivation layer 420 is made of silicon nitride. In one embodiment, the bottom and top passivation layers 410, 420 each have a thickness of about 0.5 to 2.0 micrometers, and ideally 1.0 micrometers. A capacitor device is formed between the bottom and top passivation layers 410, 420. By forming the capacitor device in the passivation structure 400 instead of the backend interconnect stack 300, it eliminates any parasitic capacitance that might arise between the capacitor device and metal layers in backend interconnect stack 300. Furthermore, fabricating the capacitor device in the passivation structure 400 does not consume the area in the backend interconnect stack 300 used for routing of metal layers.

In an embodiment of the present invention, the capacitor device is a metal-insulator-metal (MIM) capacitor comprising a bottom electrode 511, a top electrode 521 and a dielectric layer 611 formed between the bottom and top electrodes 511, 521. The bottom and top electrodes 511, 521 have the capability to store electrical charge or energy between them.

In one embodiment, the bottom electrode 511 is formed on the bottom passivation layer 410 as shown in FIG. 2. In an embodiment of the present invention, the bottom electrode 511 comprises a bottom plate 514 having a terminal region 519. In one embodiment, the bottom plate 514 is substantially planar. A first interconnect 391 electrically couples the terminal region 519 of the bottom electrode 511 to the metal layer 341 in the topmost interlayer dielectric 340.

In an embodiment of the present invention, the top electrode 521 is disposed above the bottom electrode 511. In one embodiment, the top electrode 521 comprises a top plate 524 having a terminal region 529, wherein the top plate 524 is parallel to the bottom plate 514 of the bottom electrode 511. In one embodiment, the top plate 524 is substantially planar. A second interconnect 392 electrically couples the terminal region 529 of the top electrode 521 to the metal layer 343 in the topmost interlayer dielectric 340.

Both the bottom and top electrodes 511, 521 are made of any conductive materials such as metals or metal alloys. In one embodiment, the bottom and top electrodes 511, 521 are made of a refractory metal, such as but not limited to titanium (Ti), titanium nitride (TiN), tantalum (Ta), or tantalum nitride (TaN). In one embodiment, the thickness of each of the electrodes 511, 521 is about 20 to 50 nanometers, and ideally 35 nanometers.

FIG. 3 is a top plan view of the capacitor device in FIG. 2. For illustration purposes, FIG. 3 is shown without the top passivation layer 420. In one embodiment, the bottom plate 514 is a single continuous plate. Top plate 524 is also a single continuous plate that is disposed above the bottom plate 514. In one embodiment, each of the plates 514, 524 has an area of about 200×300 square micrometers. Viewing into line A-A in FIG. 3 shows the cross-sectional view of the capacitor device in FIG. 2.

Referring back to FIG. 2, dielectric layer 611 is formed between the bottom electrode 511 and top electrode 521. In an embodiment of the present invention, the dielectric layer 611 is made of well known insulative materials, such as but not limited to silicon nitride (e.g., Si₃N₄), having a thickness of around 10 to 20 nanometers. In another embodiment, the dielectric layer 611 is made of a high-k dielectric material (i.e. k >6). For example, the high-k dielectric material is a metal oxide dielectric, such as but not limited to tantalum oxide (Ta₂O₅), titanium oxide (TiO₂) and hafnium oxide (HfO₂). In another embodiment, the dielectric layer 611 is made of lead zirconate titanate (PZT) or barium strontium titanate (BST). In the case of using the high-k dielectric material, the thickness of the dielectric layer 611 is about 3 to 10 nanometers, and ideally 5 nanometers. One advantage of fabricating the capacitor device in the passivation structure 400 is the benefit of using a high-k dielectric layer 611 to increase the capacitance of the capacitor device without affecting the capacitance of the backend interconnect stack 300.

In one embodiment, the first interconnect 391 comprises an adhesion layer 361 that provides good adhesion to the metal layer 341 and the bottom and top passivation layers 410, 420. Similarly, the second interconnect 392 comprises an adhesion layer 362 that provides good adhesion to the metal layer 343 and the bottom and top passivation layers 410, 420. The adhesion layers 361, 362 are made of materials such as but not limited to titanium (Ti), titanium tungsten (TiW) or tantalum (Ta). In one embodiment, the adhesion layers 361, 362 have a thickness of about 500 to 1500 Angstroms.

In an embodiment of the present invention, the sidewalls of the first interconnect 391 includes a step 396 that is adjacent to the terminal region 519 of bottom electrode 511. In other words, the portion of the first interconnect 391 above the terminal region 519 has a larger width than the portion below the terminal region 519 so that the sidewalls include step 396. Similarly, the sidewalls of the second interconnect 392 includes step 397 that is adjacent to the terminal region 529 of the top electrode 521. The steps 396, 397 provides better contact resistance so that the first and second interconnects 391, 392 can achieve low resistance contact.

In an embodiment of the present invention, a first metal layer 393 is formed on the first interconnect 391, and a second metal layer 394 is formed on the second interconnect 392. In one embodiment, first metal layer 393 and first interconnect 391 are formed in the same processing step. In this case, the first metal layer 393 and first interconnect 391 are made of the same metal or metal alloy materials, such as but not limited to aluminum (Al), titanium (Ti), copper (Cu) and tungsten (W). Similarly, the second metal layer 393 and second interconnect 394 can be fabricated from the same processing step and made of similar materials as the first metal layer 393 and first interconnect 391. In one embodiment, the first and second metal layer 393, 394 each has a thickness of about 5 to 10 micrometers.

In one embodiment, a first solder bump 398 is formed on first metal layer 393 and a second solder bump 399 is formed on second metal layer 394. The first and second solder bumps 398, 399 serve as electrical connections between the semiconductor device and a package substrate or circuit board. In one embodiment, the first and second solder bumps 398, 399 are part of a Controlled Collapse Chip Connection (C4) that can be attached to conductive traces of a package substrate. First and second solder bumps 398, 399 are made from well known solder materials and are formed by well known techniques, such as but not limited to evaporation, electroplating or direct placement. In one embodiment, first and second solder bumps 398, 399 have a diameter of about 50 to 100 micrometers.

In an embodiment of the present invention, the capacitor device shown in FIG. 2 is used as a decoupling capacitor. In this case, the first interconnect 391 is electrically coupled to a positive power supply node V+ (not shown), and the second interconnect 392 is electrically coupled to a negative power supply node V− (not shown). Capacitor device serves as a decoupling capacitor for the power supplies V+ and V−. In one embodiment, the first and second interconnects 391, 392 are power supply interconnects of a pre-existent circuit layout. The capacitor device can be easily formed between these power supply interconnects to decouple the circuit without modifying or affecting the existing circuit layout. It can be appreciated that the capacitor device is not limited to be used as a decoupling capacitor but can be used for other purposes, such as a noise filter means or sensing means.

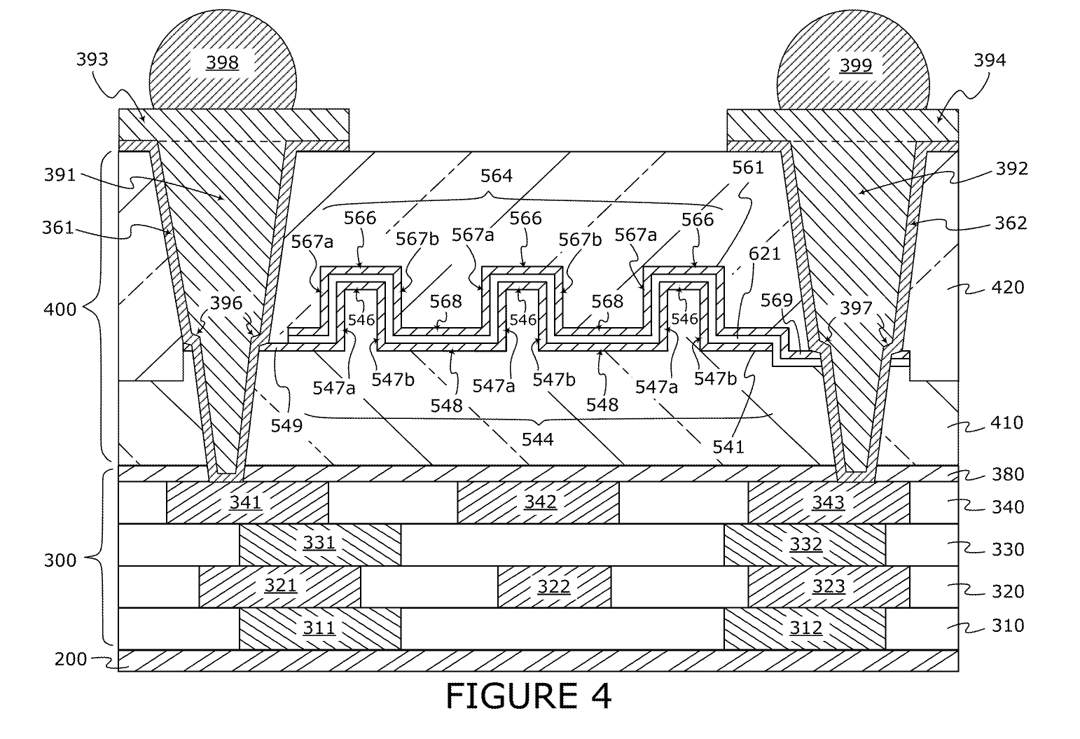

FIG. 4 illustrates a semiconductor device comprising an alternative embodiment of the capacitor device. Similar to FIG. 2, the capacitor device as shown in FIG. 4 is formed between the bottom and top passivation layers 410, 420 of the passivation structure 400. By forming the capacitor device in the passivation structure 400 instead of the backend interconnect stack 300, it eliminates any parasitic capacitance that might arise between the capacitor device and metal layers in backend interconnect stack 300. Capacitor device comprises a bottom electrode 541, a top electrode 561 and a dielectric layer 621 formed between the bottom and top electrodes 541, 561. The bottom and top electrodes 541, 561 have the capability to store electrical charge or energy between them. Both the bottom and top electrodes 541, 561 are made of similar materials as the electrodes 511, 521 described in relation to FIG. 2.

In an embodiment of the present invention, the bottom electrode 541 comprises a corrugated bottom plate 544 having a terminal region 549. The corrugated bottom plate 544 includes a plurality of lower ridges. Each lower ridge comprises an upper layer 546, a first sidewall 547a and a second sidewall 547b, wherein each of the first and second sidewalls 547a, 547b extend from opposite sides of the upper layer 546 to a lower layer 548. The first sidewall 547a of each lower ridge is coupled to the second sidewall 547b of an adjacent lower ridge by a lower layer 548.

In one embodiment, the upper layers 546, first and second sidewalls 547a, 547b, and lower layers 548 have substantially equal thickness with a range of about 10 to 15 nanometers. FIG. 4 shows the corrugated bottom plate 544 having three ridges. However, it can be appreciated that the corrugated bottom plate 544 is not limited to only three ridges but may comprise greater or lesser than three ridges. In one embodiment, the corrugated bottom plate 544 comprises at least one lower ridge.

In one embodiment, the top electrode 561 is disposed above the bottom electrode 541. The top electrode 561 comprises a corrugated top plate 564 having a terminal region 569. Corrugated top plate 564 includes a plurality of upper ridges. Each upper ridge comprises an upper layer 566, a first sidewall 567a and a second sidewall 567b, wherein each of the first and second sidewalls 567a, 567b extend from opposite sides of the upper layer 566 to a lower layer 568. The first sidewall 567a of each upper ridge is coupled to the second sidewall 567b of an adjacent upper ridge by a lower layer 568.

In one embodiment, the corrugated top plate 564 is parallel and complementarily shaped with respect to the corrugated bottom plate 544 such that the upper ridges of corrugated top plate 564 are overlying the lower ridges of corrugated bottom plate 544. In particular, the upper layers 566, sidewalls 567a, 567b, and lower layers 568 of corrugated top plate 564 are overlying the upper layers 546, sidewalls 547a, 547b, and lower layers 548 of corrugated bottom plate 544.

In one embodiment, the upper layers 566, first and second sidewalls 567a, 567b and lower layers 568 of the corrugated top plate 564 have substantially equal thickness with a range of about 10 to 15 nanometers. In one embodiment, the corrugated top plate 564 and corrugated bottom plate 544 have substantially equal thickness. In one embodiment, the corrugated top plate 564 has the same number of ridges with respect to the corrugated bottom plate 544. As shown in FIG. 4, the corrugated top plate 564 has three upper ridges overlying three lower ridges of the corrugated bottom plate 544. In one embodiment, the corrugated top plate 564 and corrugated bottom plate 544 comprises at least one ridge each.

Similar to FIG. 2, the first interconnect 391 electrically couples the terminal region 549 of the bottom electrode 541 to the metal layer 341 in the topmost interlayer dielectric 340. The second interconnect 392 electrically couples the terminal region 569 of the top electrode 561 to the metal layer 343 in the topmost interlayer dielectric 340. The first interconnect 391 and second interconnect 392 comprises the step 396 and step 397 respectively. Similarly, first metal layer 393 is formed on the first interconnect 391 and second metal layer 394 is formed on the second interconnect 392. Solder bumps 398, 399 are formed on the first and second metal layers 393, 394.

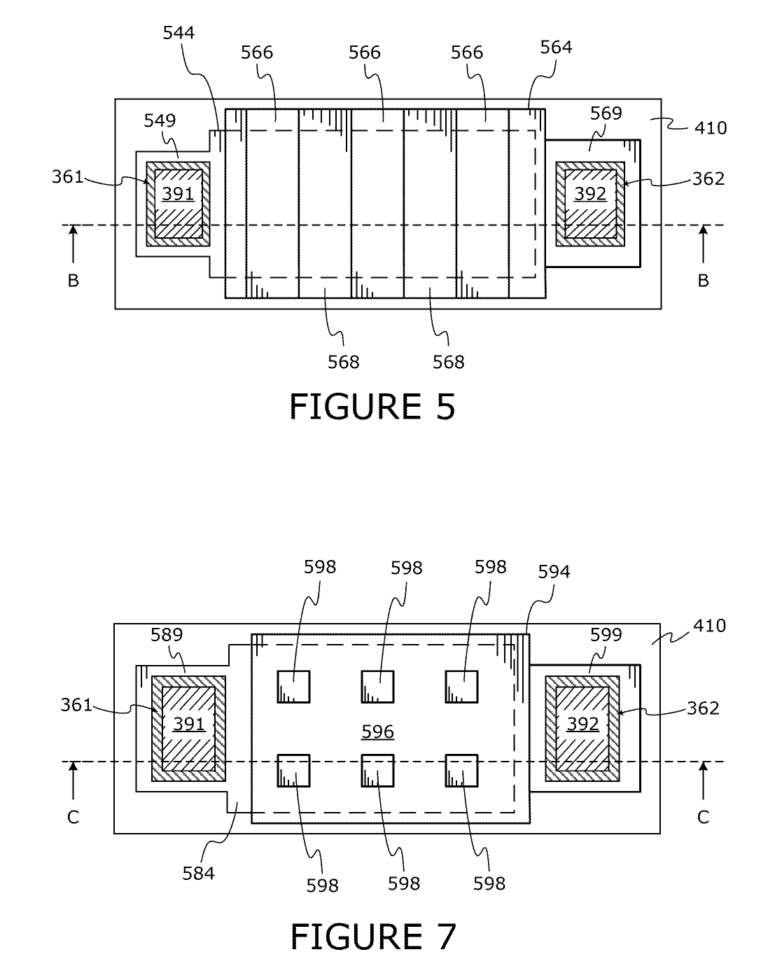

FIG. 5 is a top plan view of the capacitor device in FIG. 4. For illustration purposes, FIG. 5 is shown without the top passivation layer 420. In one embodiment, the corrugated top plate 564 is a single continuous plate. FIG. 5 shows the corrugated top plate 564 having three ridges as identified by their upper layers 566. Viewing into line B-B in FIG. 5 shows the cross-sectional view of the capacitor device in FIG. 4. The corrugated plates 544, 564 both have a larger surface area with respect to the planar plates 514, 524 in FIGS. 2 and 3, and are therefore able to produce larger capacitance.

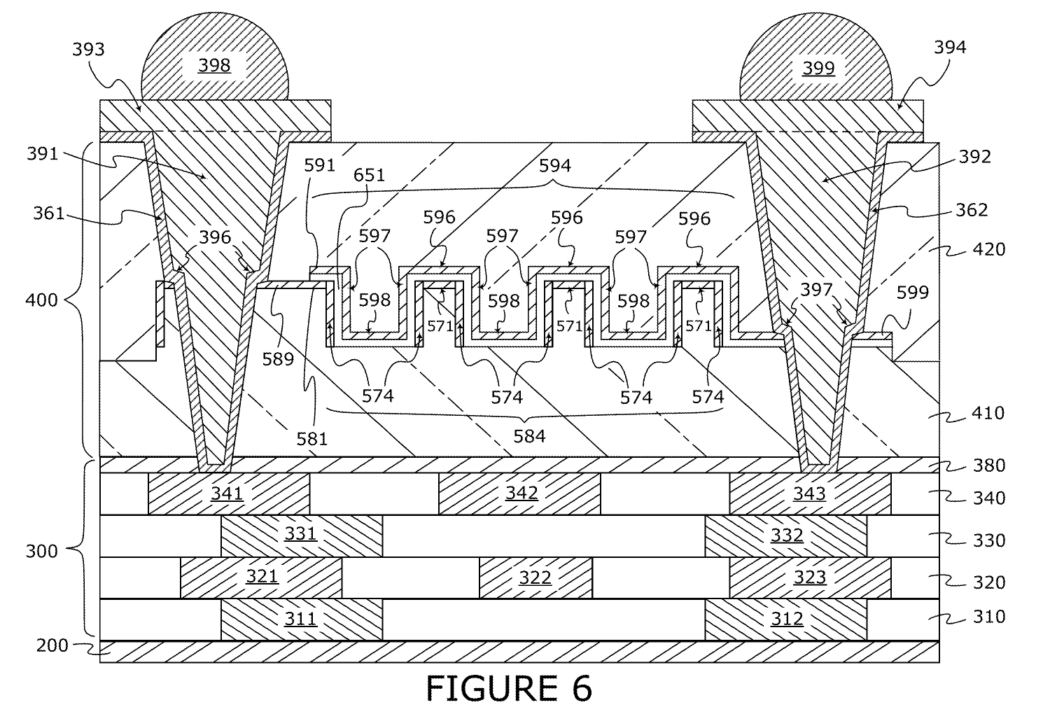

FIG. 6 illustrates a semiconductor device comprising an alternative embodiment of the capacitor device. Similar to FIG. 2, the capacitor device as shown in FIG. 6 is formed between the bottom and top passivation layers 410, 420 of the passivation structure 400. By forming the capacitor device in the passivation structure 400 instead of the backend interconnect stack 300, it eliminates any parasitic capacitance that might arise between the capacitor device and metal layers in backend interconnect stack 300. Capacitor device comprises a bottom electrode 581, a top electrode 591 and a dielectric layer 651 formed between the bottom and top electrodes 581, 591. The bottom and top electrodes 581, 591 have the capability to store electrical charge or energy between them. Both the bottom and top electrodes 581, 591 are made of the similar materials as the electrodes 511, 521 described in relation to FIG. 2.

In an embodiment of the present invention, the bottom electrode 581 comprises a waffle-shaped bottom plate 584 having a terminal region 589. The waffle-shaped bottom plate 584 includes a plurality of lower recesses. Each lower recess comprises sidewalls 574 extending from an upper layer 571 of bottom plate 584. In one embodiment, the upper layer 571 and sidewalls 574 have substantially equal thickness with a range of about 10 to 15 nanometers. FIG. 6 shows the waffle-shaped bottom plate 584 having three recesses. However, it can be appreciated that the waffle-shaped bottom plate 584 is not limited to only three recesses but may comprise greater or lesser than three recesses. In one embodiment, the waffle-shaped bottom plate 584 comprises at least one recess.

In one embodiment, the top electrode 591 is disposed above the bottom electrode 581. Top electrode 591 comprises a waffle-shaped top plate 594 having a terminal region 599. Waffle-shaped top plate 594 includes a plurality of upper recesses. Each upper recess comprises sidewalls 597 extending from an upper layer 596 of top plate 594 to a lower layer 598. In one embodiment, the upper layer 596, sidewalls 597, and lower layers 598 have substantially equal thickness with a range of about 10 to 15 nanometers. In one embodiment, the waffle-shaped top plate 594 and waffle-shaped bottom plate 584 have substantially equal thickness.

In one embodiment, the waffle-shaped top plate 594 is parallel and complementarily shaped with respect to the waffle-shaped bottom plate 584 such that the upper recesses of waffle-shaped top plate 594 are overlying the lower recesses of waffle-shaped bottom plate 584. In particular, the upper layer 596 and sidewalls 597 of waffle-shaped top plate 594 are overlying the upper layer 571 and sidewalls 574 of waffle-shaped bottom plate 584.

In one embodiment, the waffle-shaped top plate 594 has the same number of recesses with respect to the waffle-shaped bottom plate 584. As shown in FIG. 6, the waffle-shaped top plate 594 has three upper recesses overlying three lower recesses of the waffle-shaped bottom plate 584. In one embodiment, the waffle-shaped top plate 594 and waffle-shaped bottom plate 584 comprises at least one recess each.

Similar to FIG. 2, the first interconnect 391 electrically couples the terminal region 589 of the bottom electrode 581 to the metal layer 341 in the topmost interlayer dielectric 340. The second interconnect 392 electrically couples the terminal region 599 of the top electrode 591 to the metal layer 343 in the topmost interlayer dielectric 340. The first interconnect 391 and second interconnect 392 comprises the step 396 and step 397 respectively. Similarly, first metal layer 393 is formed on the first interconnect 391 and second metal layer 394 is formed on the second interconnect 392. Solder bumps 398, 399 are formed on the first and second metal layers 393, 394.

FIG. 7 is a top plan view of the capacitor device in FIG. 6. For illustration purposes, FIG. 7 is shown without the top passivation layer 420. In one embodiment, the waffle-shaped top plate 594 comprises six recesses as identified by their lower layer 598. The six recesses are arranged in a 2×3 arrangement. However, it can be appreciated that the waffle-shaped top plate 594 can have greater or lesser than six recesses. Viewing into line C-C in FIG. 7 shows the cross-sectional view of the capacitor device in FIG. 6. The waffle-shaped plates 584, 594 in FIG. 6 both have a larger surface area with respect to the planar plates 514, 524 in FIG. 2, and are therefore able to provide a larger capacitance.

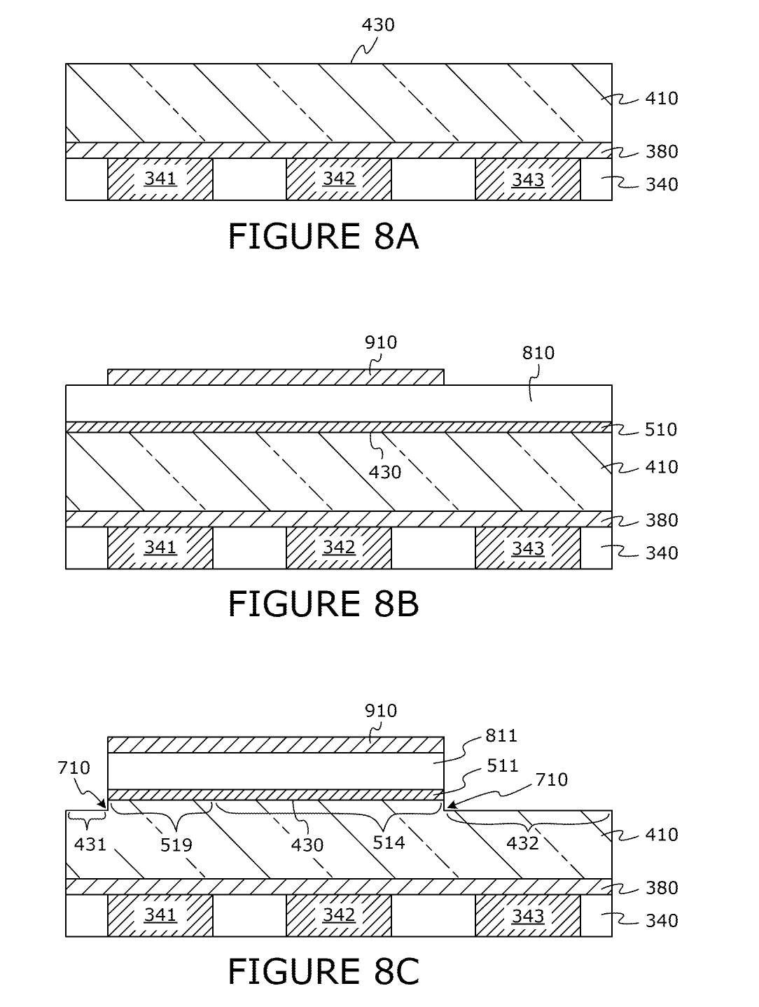

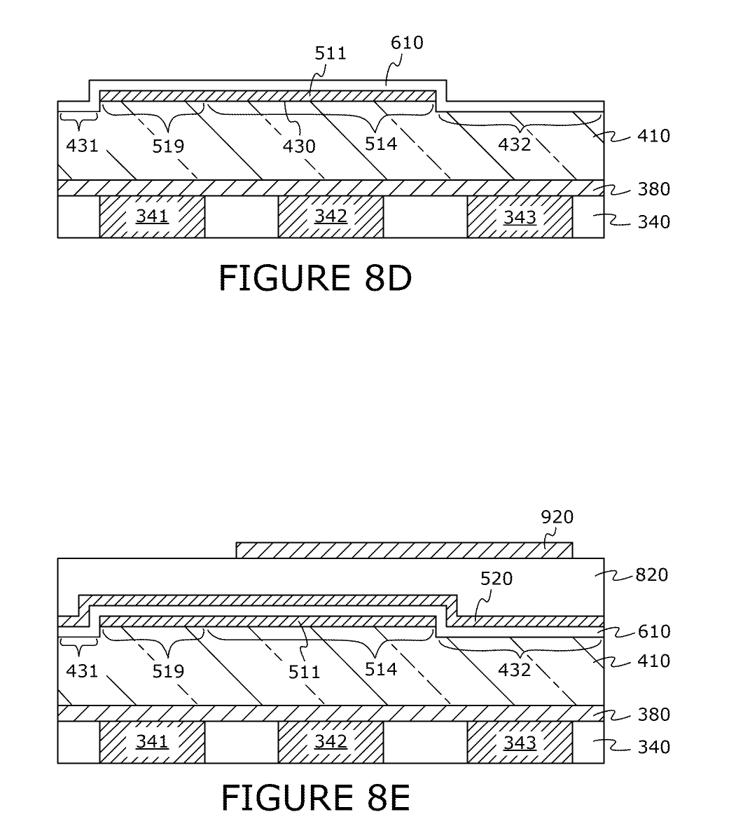

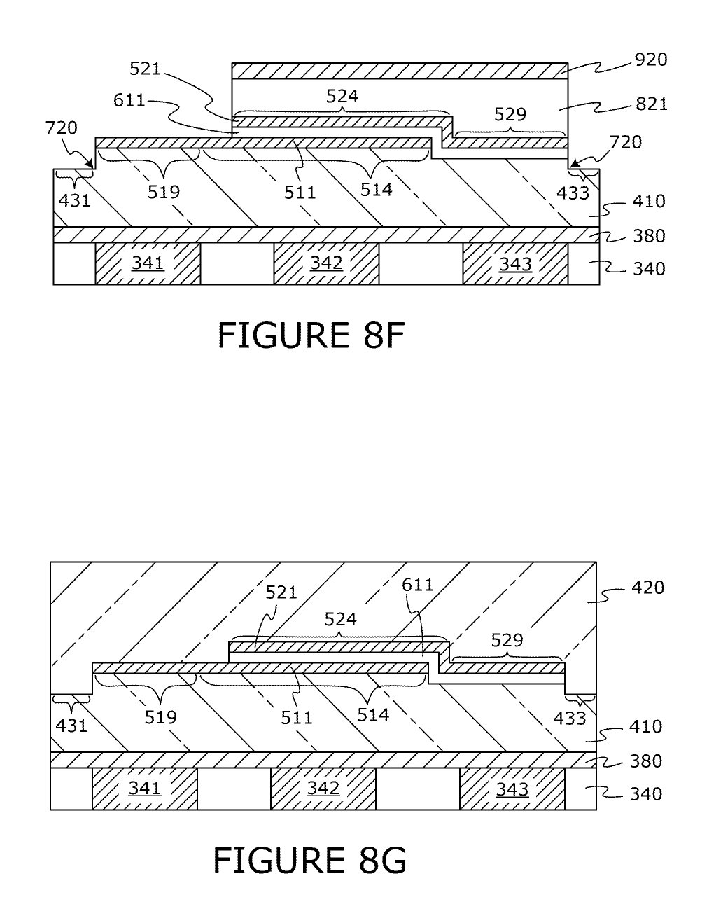

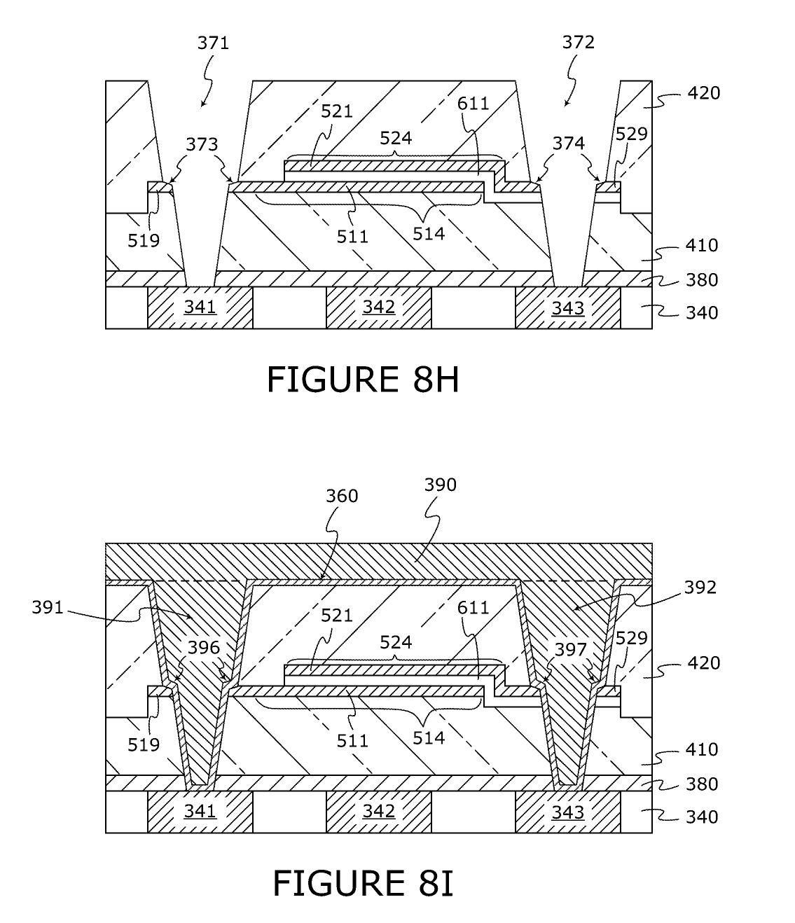

FIGS. 8A-81 illustrate a method of forming the semiconductor device having the capacitor device as shown in FIG. 2 in accordance with one embodiment of the present invention. The fabrication of the semiconductor device begins by providing a substrate 200 having a backend interconnect stack 300 formed thereon. The substrate 200 and backend interconnect stack 300 are similar to the embodiments described with respect to FIG. 2 and thus will not be discussed in detail here. Briefly, the backend interconnect stack 300 includes a topmost interlayer dielectric 340. The topmost interlayer dielectric 340 includes metal layers 341, 342, 343 as shown in FIG. 8A. In one embodiment, an etch stop layer 380 is formed on the topmost interlayer dielectric 340. For simplicity purposes, only the topmost interlayer dielectric 340 of the backend interconnect stack 300 is illustrated in FIGS. 8A-8I.

Next, a bottom passivation layer 410 is deposited above the topmost interlayer dielectric 340 as shown in FIG. 8A. In an embodiment of the present invention, the bottom passivation layer 410 is blanket deposited on the etch stop layer 380 formed on the topmost dielectric layer 340. Bottom passivation layer 410 includes a top surface 430. The bottom passivation layer 410 is made of the same types of materials as described in relation to FIG. 2. The bottom passivation layer 410 can be formed by any well known methods, such as but not limited to physical vapor deposition (PVD) or chemical vapor deposition (CVD).

Next, a bottom electrode of the capacitor device is formed on the bottom passivation layer 410. In an embodiment of the present invention, the fabrication of the bottom electrode begins by blanket depositing a conductive layer 510 onto the top surface 430 of bottom passivation layer 410 as shown in FIG. 8B. In one embodiment, a sacrificial material 810 is blanket deposited on the conductive layer 510 before a photoresist mask 910 is formed on the sacrificial material 810. In another embodiment, photoresist mask 910 is formed directly on the conductive layer 510 without any intermediate sacrificial material.

In an embodiment of the present invention, the conductive layer 510 is made of metals or metal alloys. In one embodiment, the conductive layer 510 is made of a refractory metal, such as but not limited to titanium nitride (TiN) or tantalum nitride (TaN). In one embodiment, the thickness of the conductive layer 510 is about 20 to 50 nanometers, and ideally 35 nanometers. The conductive layer 510 can be formed by any well known methods, such as but not limited to physical vapor deposition (PVD), chemical vapor deposition (CVD) or atomic layer deposition (ALD).

In an embodiment of the present invention, the sacrificial material 810 is a sacrificial light absorbing material (SLAM) to enable the formation of the bottom electrode on the bottom passivation layer 410. In one embodiment, the sacrificial material 810 provides an anti-reflective coating for the lithographic processing of the photoresist mask 910 used to define the location of bottom electrode. As such, in an embodiment of the present invention, the sacrificial material 810 is formed on the conductive layer 510 and has the capability to act as an anti-reflective coating for exposure to light/radiation. Sacrificial material 810 can be made from any well known materials and deposited by any well known techniques, such as but not limited to spin on techniques.

In one embodiment, photoresist mask 910 is formed on the sacrificial material 810 to define a desired portion of the conductive layer 510 to form the bottom electrode. Photoresist mask 910 can be made from any well known materials. Photoresist mask 910 can be formed by any well known photolithography techniques, such as masking, exposing and developing.

Next, in FIG. 8C, an etching process is performed in alignment to the photoresist mask 910 to form the bottom electrode from a desired portion of the conductive layer 510. In particular, the etching process removes any portions of the conductive layer 510 not covered by the photoresist mask 910 to form bottom electrode 511 on the bottom passivation layer 410. In an embodiment of the present invention, the bottom electrode 511 comprises a bottom plate 514 having a terminal region 519. In one embodiment, the bottom plate 514 is substantially planar.

Furthermore, the etching process also removes any portions of the sacrificial material 810 not covered by the photoresist mask 910 so that only a remaining portion 811 of the sacrificial material 810 is left on the bottom electrode 511. The etching process uses well known dry-etch or wet-etch techniques. In one embodiment, the etching process uses an etchant chemistry that selectively removes portions of the sacrificial material 810 and conductive layer 510 not covered by the photoresist mask 910. Removing portions of the sacrificial material 810 and conductive layer 510 not covered by the photoresist mask 910 also exposes region 431 and region 432 of the bottom passivation layer 410, wherein exposed region 431 is adjacent to the terminal region 519 and exposed region 432 is adjacent to bottom plate 514.

In one embodiment, the etching process may cause an over-etch 710 at the exposed regions 431, 432 of the bottom passivation layer 410 which are not covered by the photoresist mask 910. However, the bottom passivation layer 410 has sufficient thickness to prevent any defects resulting from the over-etch 710.

After etching is complete, both the photoresist mask 910 and the remaining portion 811 of the sacrificial material are removed from the bottom electrode 511. The photoresist mask 910 and remaining portion 811 of sacrificial material can be removed by well known techniques, such as but not limited to plasma ashing. Subsequently, an optional cleaning process can be performed on the bottom electrode 511 to remove any contaminants thereon. Bottom electrode 511 can be cleaned by any well known cleaning solutions.

Next, a dielectric layer is formed on the bottom electrode 511. In an embodiment of the present invention, a dielectric layer 610 is blanket deposited onto the entire bottom electrode 511 as shown in FIG. 8D. Furthermore, the dielectric layer 610 is also deposited onto the exposed regions 431, 432 of bottom passivation layer 410. The dielectric layer 610 is made from the same materials as the dielectric layer 611 described in relation to FIG. 2, and thus will not be discussed in detail here. In one embodiment, the dielectric layer 610 is deposited by well known methods such as but not limited to physical vapor deposition (PVD), chemical vapor deposition (CVD) or atomic layer deposition (ALD).

Next, the top electrode of the capacitor device is formed on the dielectric layer. In an embodiment of the present invention, the fabrication of the top electrode begins by blanket depositing a conductive layer 520 onto the dielectric layer 610 as shown in FIG. 8E. The conductive layer 520 is made from the same materials and techniques used in fabricating the conductive layer 510 in FIG. 8B, and hence will not be described in detail here. In one embodiment, a sacrificial material 820 is blanket deposited on the conductive layer 520. Sacrificial material 820 is made from the same materials and techniques used for the sacrificial material 810 described in FIG. 8B. A photoresist mask 920 is then formed on the sacrificial material 820 to define a desired portion of the conductive layer 520 to form the top electrode. The photoresist mask 920 is made from the same materials and techniques used in fabricating the photoresist mask 910 in FIG. 8B, and hence will not be described in detail here. In another embodiment, the photoresist mask 920 is formed directly onto the conductive layer 520 without any intermediate sacrificial material.

Next, an etching process is performed in alignment to the photoresist mask 920 to form a top electrode from a desired portion of conductive layer 520. In particular, the etching process removes any portions of the conductive layer 520 not covered by the photoresist mask 920 to form the top electrode 521 as shown in FIG. 8F. In one embodiment, a portion of the conductive layer 520 that is above the terminal region 519 of the bottom electrode 511 is removed during the etching process. In an embodiment of the present invention, the top electrode 521 comprises a top plate 524 having a terminal region 529. The top plate 524 is disposed above bottom plate 514 of the bottom electrode 511, wherein top plate 524 is parallel to bottom plate 514. In one embodiment, the top plate 524 is substantially planar.

In an embodiment of the present invention, the etching process may further remove any portions of the dielectric layer 610 not covered by the photoresist mask 920. In this case, a remaining portion 611 of the dielectric layer 610 is left between top plate 524 and bottom plate 514. Hereinafter, the remaining portion 611 is referred to as dielectric layer 611. As a result, the terminal region 519 of the bottom electrode 511 is exposed. Furthermore, region 431 and region 433 of bottom passivation layer 410 are exposed by the etching process. Region 433 of the bottom passivation layer 410 is adjacent to the terminal region 529 of top electrode 521.

Furthermore, the etching process also removes any portions of the sacrificial material 820 not covered by the photoresist mask 910 so that only a remaining portion 821 of the sacrificial material 820 is left on the top electrode 521. The etching process uses well known dry-etch or wet-etch techniques. In one embodiment, the etching process uses an etchant chemistry that selectively removes portions of the sacrificial material 820 and conductive layer 520 not covered by the photoresist mask 920.

In one embodiment, the etching may cause an over-etch 720 at the exposed regions 431, 433 of bottom passivation layer 410. However, the bottom passivation layer 410 has sufficient thickness to prevent any defects resulting from the over-etch 720.

After etching is complete, both the photoresist mask 920 and the remaining portion 821 of sacrificial material are removed from the top electrode 521 using well known techniques, such as plasma ashing. An optional cleaning step can also be performed on the top electrode 521 to remove any contaminants thereon.

Next, a top passivation layer 420 is deposited over the top electrode 521 as shown in FIG. 8G. In an embodiment of the present invention, the top passivation layer 420 is deposited over the entire top electrode 521 as well as the terminal region 519 of the bottom electrode 511. Furthermore, the top passivation layer 420 is also deposited onto the exposed regions 431, 433 of the bottom passivation layer 410. The top passivation layer 420 is made of the same materials as described in relation to FIG. 2. Top passivation layer 420 can be formed by any well known methods, such as but not limited to PVD or CVD.

A first interconnect 391 and a second interconnect 392 are then formed to electrically couple the bottom electrode 511 and top electrode 521 to the metal layers in the topmost interlayer dielectric 340. In an embodiment of the present invention, fabrication of the first interconnect 391 begins, in FIG. 8H, by forming a first via or opening 371 that extends from the top surface of the top passivation layer 420 to the metal layer 341 in the topmost interlayer dielectric 340. In particular, the first via 371 extends through the terminal region 519 of the bottom electrode 511.

Similarly, a second via or opening 372 is formed to extend from the top surface of the top passivation layer 420 to the metal layer 343 in the topmost interlayer dielectric 340. In particular, the second via extends through the terminal region 529 of the top electrode 521. In an embodiment of the present invention, the second via 372 is formed at the same time as the first via 371.

In an embodiment of the present invention, the first via 371 and second via 372 is formed by a dry-etching process that uses an etchant chemistry with a higher selectivity to the bottom passivation layer 410. In the case where the top passivation layer 420 is made of silicon nitride (SiN) and the bottom passivation layer 410 is made of silicon dioxide (SiO₂), the dry-etching process uses a fluorine-based chemistry that etches the SiN top passivation layer 420 faster than the SiO₂ bottom passivation layer 410 or the bottom and top electrodes 511, 521. As a result, a step 373 is formed at the sidewalls of the first via 371, where the step 373 is adjacent to the terminal region 519 of the bottom electrode 511. Similarly, a step 374 is formed at the sidewalls of the second via 372, where the step 374 is adjacent to the terminal region 529 of the top electrode 521. After forming the first via 371 and second via 372, a cleaning process can be performed to remove any etch polymer or residue from the first via 371 and second via 372.

Subsequently, a metal layer 390 is deposited into the first via 371 and second via 372, and also deposited on top of the top passivation layer 420 as shown in FIG. 8I. In an embodiment of the present invention, an adhesion layer 360 is deposited onto the first via 371 and second via 372 before depositing the metal layer 390. The adhesion layer 360 can be deposited by any well known techniques such as but not limited to sputtering. Then, the metal layer 390 is deposited onto the adhesion layer 360. The portion of the metal layer 390 deposited into the first via 371 forms the first interconnect 391, and the portion deposited into the second via 372 forms the second interconnect 392. The first interconnect 391 includes sidewalls with the step 396 adjacent to the terminal region 519 of bottom electrode 511. Similarly, the second interconnect 392 includes sidewalls with the step 397 adjacent to the terminal region 529 of top electrode 521. The metal layer 390 can be deposited by any well known techniques such as but not limited to electroplating. In one embodiment, the thickness of the metal layer 390 deposited is around 5 to 10 micrometers.

Next, the portions of both the adhesion layer 360 and metal layer 390 deposited on top of the top passivation layer 420 can be patterned by well known lithography and etching techniques to form the adhesion layers 361, 362 as well as the first metal layer 393 and second metal layer 394 as shown in FIG. 2. The first and second solder bumps 398, 399 are then formed onto the first and second metal layers 393, 394.

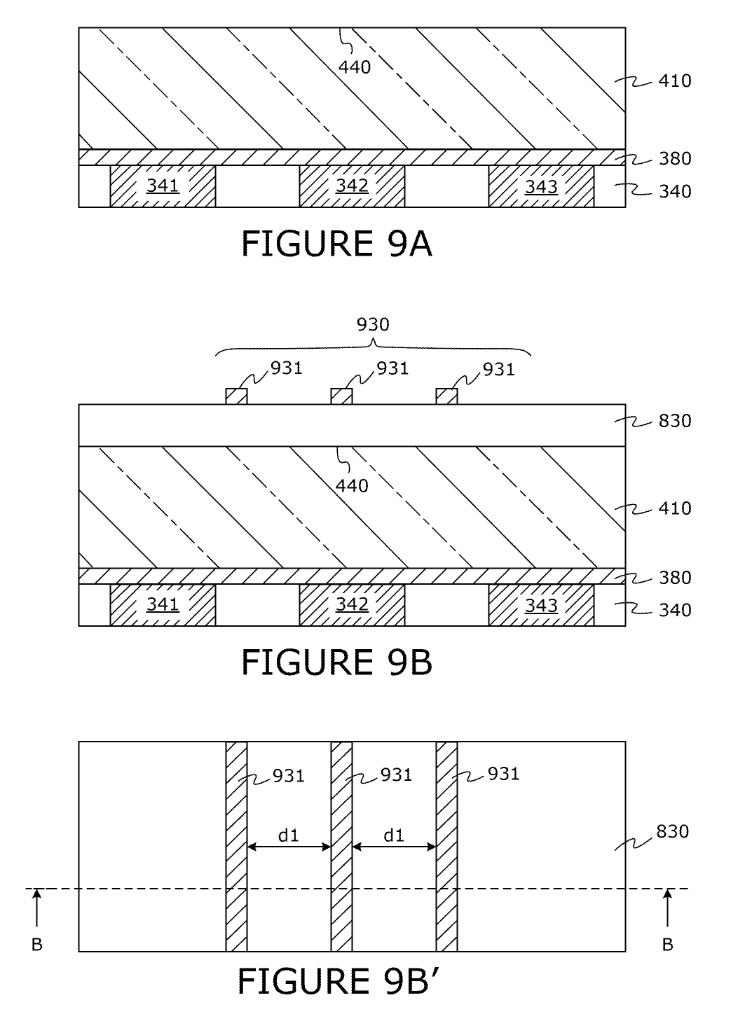

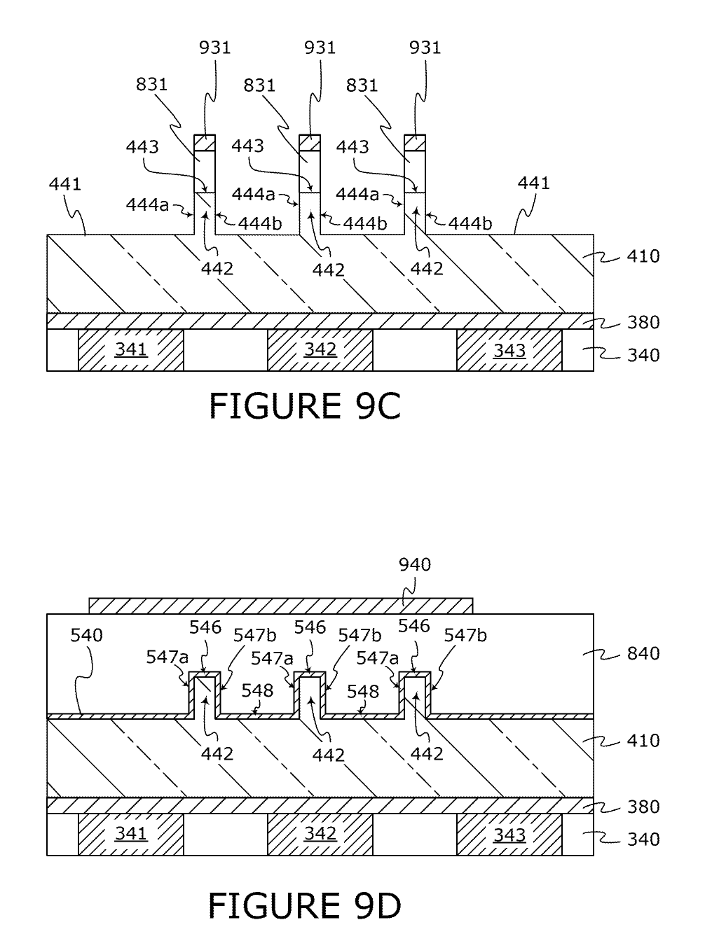

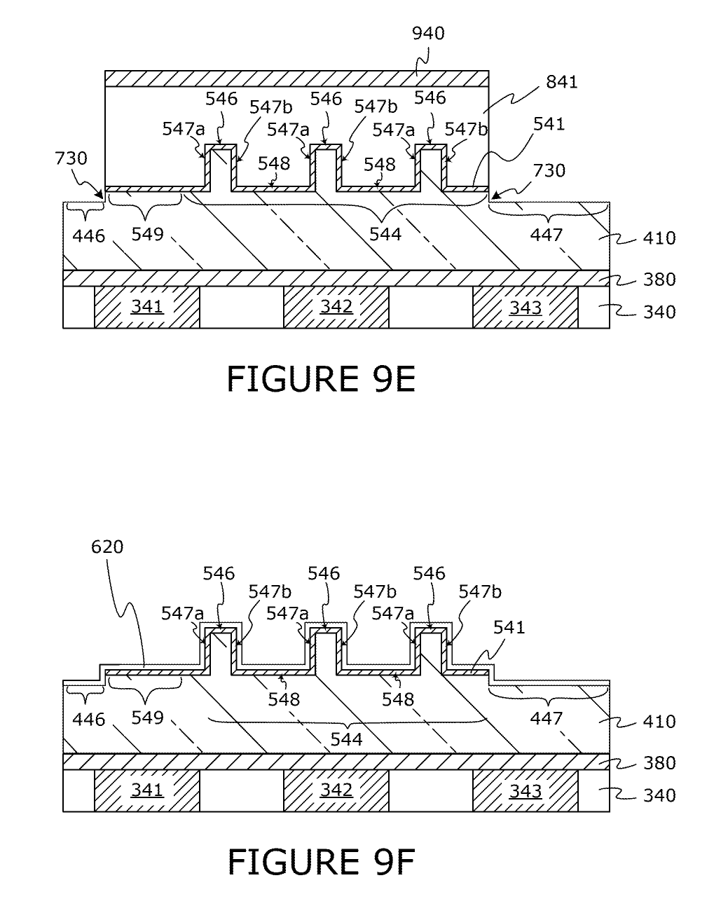

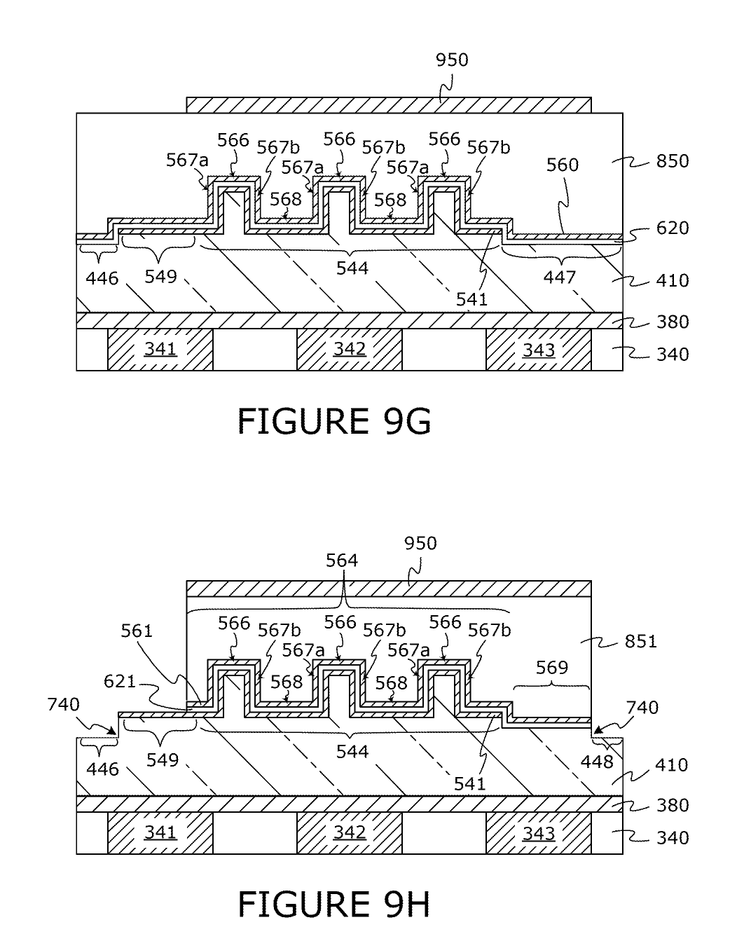

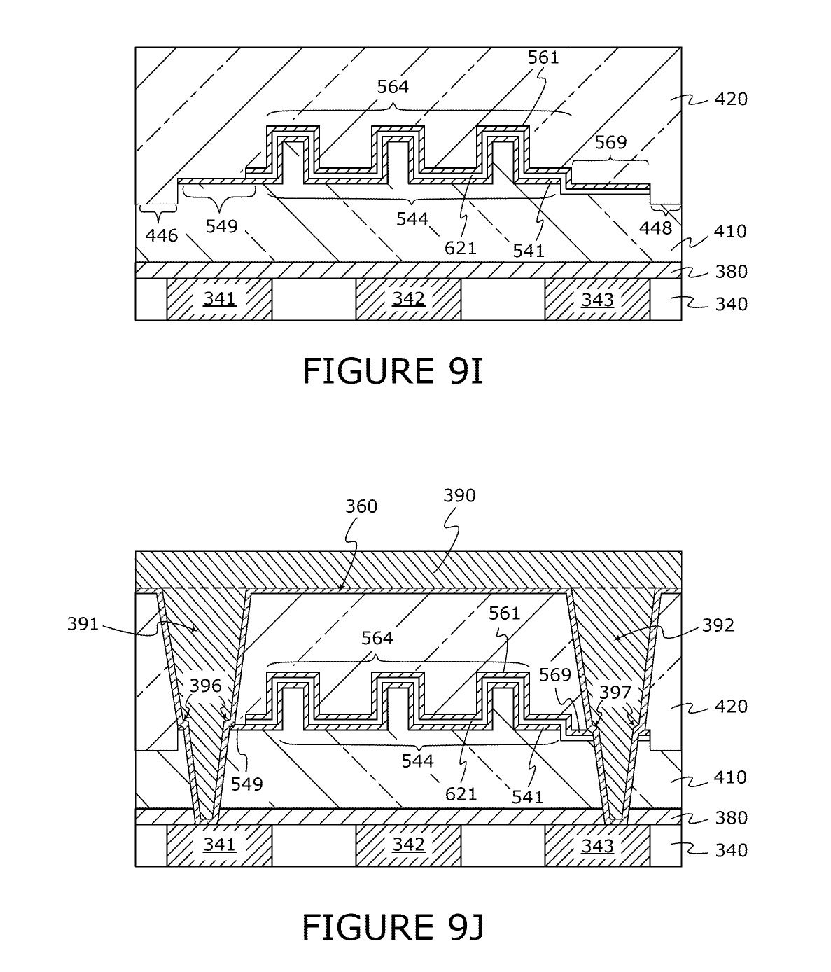

FIGS. 9A-9J illustrate a method of forming the semiconductor device having the capacitor device as shown in FIG. 4 in accordance with one embodiment of the present invention. Similar to FIG. 8A, the fabrication of the semiconductor device begins by depositing a bottom passivation layer 410 above the topmost interlayer dielectric 340 as shown in FIG. 9A. Bottom passivation layer 410 has a top surface 440. For simplicity purposes, only the topmost interlayer dielectric 340 of the backend interconnect stack 300 is illustrated in FIGS. 9A-9J.

Next, the bottom passivation layer 410 is patterned to form a corrugated surface thereon. Beginning from FIG. 9B, a sacrificial material 830 is deposited onto the top surface 440 of bottom passivation layer 410. The sacrificial material 830 uses the same types of materials and fabrication methods as the sacrificial material 810 described in relation to FIG. 8B.

A photoresist mask 930 is then formed on the sacrificial material 830. The photoresist mask 930 defines portions on the bottom passivation layer 410 to be removed so as to form the corrugated surface. FIG. 9B′ shows a top plan view of the photoresist mask 930 in FIG. 9B. In an embodiment of the present invention, the photoresist mask 930 comprises multiple strips of photoresist 931 formed on the sacrificial material 830 as shown in FIG. 9B′. In one embodiment, the multiple strips of photoresists 931 are formed parallel to each other. In one embodiment, the multiple strips of photoresist 931 are spaced apart from each other at a substantially equally distance dl. FIG. 9B′ illustrates three strips of photoresist 931. However, it can be appreciated that the photoresist mask 930 may have greater or lesser than three strips of photoresist 931. In one embodiment, the photoresist mask 930 comprises at least one strip of photoresist 931. Viewing into line B-B in FIG. 9B′ shows the cross-sectional view of the photoresist mask 930 in FIG. 9B. The photoresist mask 930 is made from the same materials and techniques used in fabricating the photoresist mask 910 in FIG. 8B, and hence will not be described in detail here.

Subsequently, in FIG. 9C, an etching process is performed in alignment to the photoresist mask 930 to form the corrugated surface on the bottom passivation layer 410. In one embodiment, the etching process removes portions of the bottom passivation layer 410 not covered by the multiple strips of photoresist 931 to define the corrugated surface comprising a plurality of fins 442. Each fin 442 comprises a top surface 443, a first sidewall 444a and a second sidewall 444b, wherein the first and second sidewalls 444a, 444b extend from opposite sides of the top surface 443 to the top surface 441 of the bottom passivation layer 410. As shown in FIG. 9C, the corrugated surface comprises three fins 442. However, it can be appreciated that the corrugated surface may have greater or lesser than three fins 442 depending on the number of strips of photoresist 931 used. In one embodiment, the corrugated surface comprises at least one fin 442.

Furthermore, the etching process also removes any portions of the sacrificial material 830 not covered by the plurality of photoresist masks 930 so that only remaining portions 831 of the sacrificial material 830 are left on top of the plurality of fins 442.

The etching process utilizes well known dry-etch or wet-etch techniques. In one embodiment, the etching process uses an etchant chemistry that selectively removes portions of the sacrificial material 830 and bottom passivation layer 410 not covered by the photoresist mask 930.

After etching is complete, the photoresist mask 930 and the remaining portions 831 of sacrificial material are removed from the plurality of fins 442 using well known techniques, such as plasma ashing. An optional cleaning process can be performed on the corrugated surface of bottom passivation layer 410 to remove any contaminants thereon.

Next, a bottom electrode of the capacitor device is formed on the bottom passivation layer 410. In an embodiment of the present invention, the fabrication of the bottom electrode begins by blanket depositing a conductive layer 540 onto the plurality of fins 444 of bottom passivation layer 410 as shown in FIG. 9D. In one embodiment, a sacrificial material 840 is blanket deposited on the conductive layer 540 before a photoresist mask 940 is formed on the sacrificial material 840. In another embodiment, the photoresist mask 940 is formed directly on the conductive layer 540 without any intermediate sacrificial material.

In one embodiment, the conductive layer 540 is deposited conformally to the plurality of fins 444 so that the conductive layer 540 has a corrugated shape comprising a plurality of lower ridges. Each lower ridge comprises an upper layer 546, a first sidewall 547a and a second sidewall 547b, wherein each of the first and second sidewalls 547a, 547b extend from opposite sides of the upper layer 546 to a lower layer 548. The first sidewall 547a of each lower ridge is coupled to the second sidewall 547b of an adjacent lower ridge by a lower layer 548. In one embodiment, the upper layers 546, sidewalls 547a, 547b and lower layers 548 have substantially equal thickness with a range of about 10 to 15 nanometers. The conductive layer 540 uses similar materials and fabrication methods as the conductive layer 510 described in FIG. 8B, and thus will not discussed in detail here.

The sacrificial material 840 is deposited on the conductive layer 540. Sacrificial material 840 uses the same types of materials and fabrication methods of the sacrificial material 810 as described in FIG. 8B. Photoresist mask 940 is formed on the sacrificial material 840 to define a desired portion of the conductive layer 540 to form the bottom electrode. In one embodiment, the photoresist mask 940 is formed above the plurality of lower ridges of conductive layer 540.

Next, in FIG. 9E, an etching process is performed in alignment to the photoresist mask 940 to form the bottom electrode 541 from a desired portion of the conductive layer 540. In particular, the etching process removes any portions of the conductive layer 540 not covered by the photoresist mask 940 to form the bottom electrode 541. In an embodiment of the present invention, the bottom electrode 541 comprises a corrugated bottom plate 544 having a terminal region 549. The corrugated bottom plate 544 includes the plurality of lower ridges, wherein each lower ridge includes upper layer 546 and sidewalls 547a, 547b extending from the upper layer 546 to lower layer 548.

Furthermore, the etching process also removes any portions of the sacrificial material 840 not covered by the photoresist mask 940 so that only a remaining portion 841 of the sacrificial material 840 is left on the bottom electrode 541.

The etching process uses well known dry-etch or wet-etch techniques. In one embodiment, the etching process uses an etchant chemistry that selectively removes portions of the sacrificial material 840 and conductive layer 540 not covered by the photoresist mask 940. Furthermore, the etching process also exposes regions 446, 447 of the bottom passivation layer 410, wherein exposed regions 446 is adjacent to terminal region 549, and wherein exposed region 447 is adjacent to the corrugated bottom plate 544.

In one embodiment, the etching process may cause an over-etch 730 at the exposed regions 446, 447 of the bottom passivation layer 410 which are not covered by the photoresist mask 940. However, the bottom passivation layer 410 has sufficient thickness to prevent any defects resulting from the over-etch 730.

After etching is complete, both the photoresist mask 940 and the remaining portion 841 of the sacrificial material 840 are removed from the bottom electrode 541 using well known techniques, such as plasma ashing. An optional cleaning process can be performed on the bottom electrode 541 to remove any contaminants thereon.

Next, a dielectric layer is formed on the bottom electrode 541. In an embodiment of the present invention, a dielectric layer 620 is blanket deposited onto the entire bottom electrode 541 as shown in FIG. 9F. In one embodiment, the dielectric layer 620 is deposited conformally onto the plurality of lower ridges of corrugated bottom plate 544 so that the dielectric layer 620 has a corrugated shape. In particular, the dielectric layer 620 is deposited conformal to the upper layers 546, sidewalls 547a, 547b and lower layers 548. Furthermore, the dielectric layer 620 is also deposited onto exposed regions 446, 447 of bottom passivation layer 410. The dielectric layer 620 is made from the same materials as the dielectric layer 611 described in relation to FIG. 2, and thus will not be discussed in detail here. In one embodiment, the dielectric material 620 is deposited by well known methods such as but not limited to PVD, CVD or ALD.

Next, the top electrode of the capacitor device is formed on the dielectric layer. In an embodiment of the present invention, the fabrication of the top electrode begins by blanket depositing a conductive layer 560 onto the dielectric layer 620 as shown in FIG. 9G. In one embodiment, the conductive layer 560 is deposited conformally to the dielectric layer 620 so that the conductive layer 560 has a corrugated shape. In particular, the conductive layer 560 comprises a plurality of upper ridges. Each upper ridge comprises an upper layer 566, a first sidewall 567a and a second sidewall 567b, wherein each of the first and second sidewalls 567a, 567b extend from opposite sides of the upper layer 566 to a lower layer 568. The first sidewall 567a of each upper ridge is coupled to the second sidewall 567b of an adjacent upper ridge by a lower layer 568. In one embodiment, the upper layers 566, sidewalls 567a, 567b and lower layers 568 have substantially equal thickness with a range of about 10 to 15 nanometers. The conductive layer 560 is made from the same materials and techniques used in fabricating the conductive layer 510 in FIG. 8B, and hence will not be described in detail here.

In one embodiment, a sacrificial material 850 is blanket deposited on the conductive layer 560. Sacrificial material 850 is made from the same materials and techniques used for the sacrificial material 810 as described in relation to FIG. 8B. A photoresist mask 950 is then formed on the sacrificial material 850 to define a desired portion of the conductive layer 560 to form a top electrode. In one embodiment, the photoresist mask 950 is formed above the plurality of upper ridges of conductive layer 560. The photoresist mask 950 is made from the same materials and techniques used in fabricating the photoresist mask 910 in FIG. 8B, and hence will not be described in detail here. In another embodiment, the photoresist mask 950 is formed directly onto the conductive layer 560 without any intermediate sacrificial material.

Next, an etching process is performed in alignment to the photoresist mask 950 to form a top electrode from a desired portion of the conductive layer 560. In particular, the etching process removes any portions of the conductive layer 560 not covered by the photoresist mask 950 to form the top electrode 561 as shown in FIG. 9H. In one embodiment, a portion of the conductive layer 560 that is above the terminal region 549 of the bottom electrode 541 is removed during the etching process. In an embodiment of the present invention, the top electrode 561 comprises a corrugated top plate 564 having a terminal region 569. The corrugated top plate 564 includes the plurality of upper ridges, wherein each upper ridge includes upper layer 566 and sidewalls 567a, 567b extending from the upper layer 566 to lower layer 568.

In an embodiment of the present invention, the etching process further removes any portions of the dielectric layer 620 not covered by the photoresist mask 950. In this case, a portion 621 of the dielectric layer 620 remains between the corrugated top plate 564 and the corrugated bottom plate 544. Hereinafter, the portion 621 is referred to as dielectric layer 621. As a result, the terminal region 549 of the bottom electrode 541 is exposed. Furthermore, region 446 and region 448 of bottom passivation layer 410 are exposed by the etching process. Region 448 of the bottom passivation layer 410 is adjacent to the terminal region 569 of top electrode 561.

Furthermore, the etching process also removes any portions of the sacrificial material 850 not covered by the photoresist mask 950 so that only a remaining portion 851 of the sacrificial material 850 is left on the top electrode 561.

The etching process uses well known dry-etch or wet-etch techniques. In one embodiment, the etching uses an etchant chemistry that selectively removes portions of the sacrificial material 850 and conductive layer 560 that are not covered by the photoresist mask 950. In one embodiment, the etching may cause an over-etch 740 at the exposed regions 446, 448 of bottom passivation layer 410. However, the bottom passivation layer 410 has sufficient thickness to prevent any defects resulting from the over-etch 740.

After etching is complete, both the photoresist mask 950 and the remaining portion 851 of sacrificial material are removed from the top electrode 561 using well known techniques, such as plasma ashing. An optional cleaning step can be performed on the top electrode 561 to remove any contaminants thereon.

Next, a top passivation layer 420 is deposited over the top electrode 561 as shown in FIG. 9I. In an embodiment of the present invention, the top passivation layer 420 is deposited over the entire top electrode 561 as well as the terminal region 549 of the bottom electrode 541. Furthermore, the top passivation layer 420 is also deposited onto the exposed regions 446, 448 of the bottom passivation layer 410. The top passivation layer 420 uses similar materials as the top passivation layer 420 described in relation to FIG. 2. The top passivation layer 420 can be formed by any well known methods, such as but not limited to PVD or CVD.

Next, in FIG. 9J, the first interconnect 391 and second interconnect 392 are formed by using the methods previously described in relation to FIGS. 8H and 8I. Briefly, a first via and a second via (not shown) are formed in the bottom and top passivation layers 410, 420, which extend through the terminal regions 549, 569 respectively. Subsequently, an adhesion layer 360 is deposited onto the first via and second via before depositing the metal layer 390.

After depositing the metal layer 390, the portions of metal layer 390 deposited on top of the top passivation layer 420 can be patterned by well known lithography and etching techniques to form the first metal layer 393 and second metal layer 394 as shown in FIG. 4. The first and second solder bumps 398, 399 are then formed onto the first and second metal layers 393, 394.

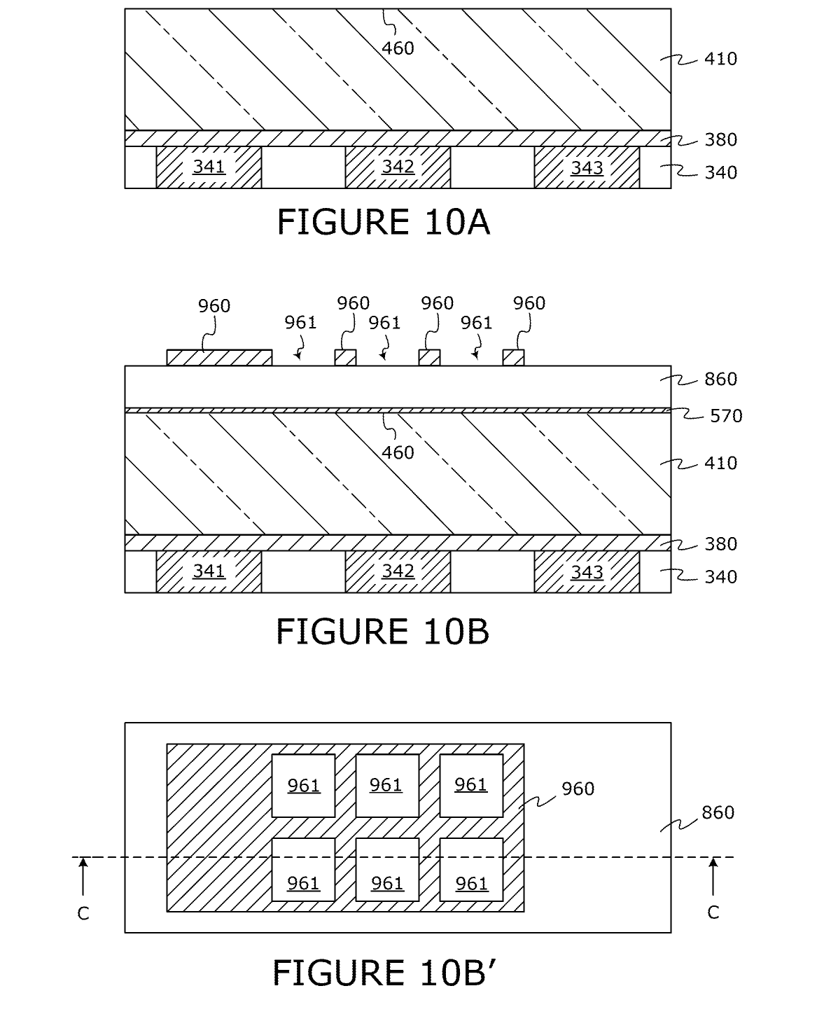

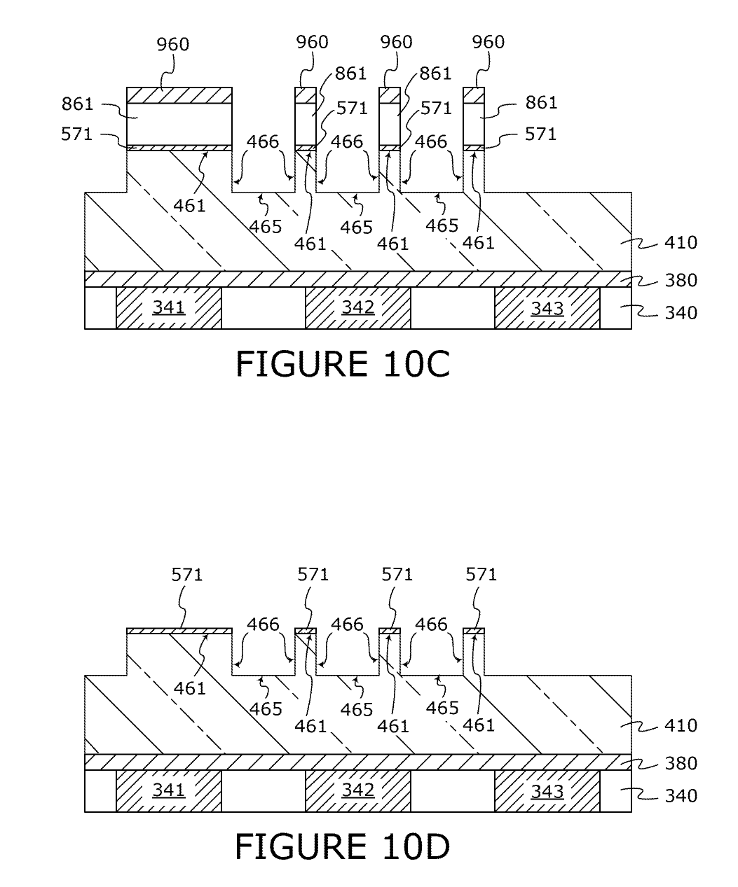

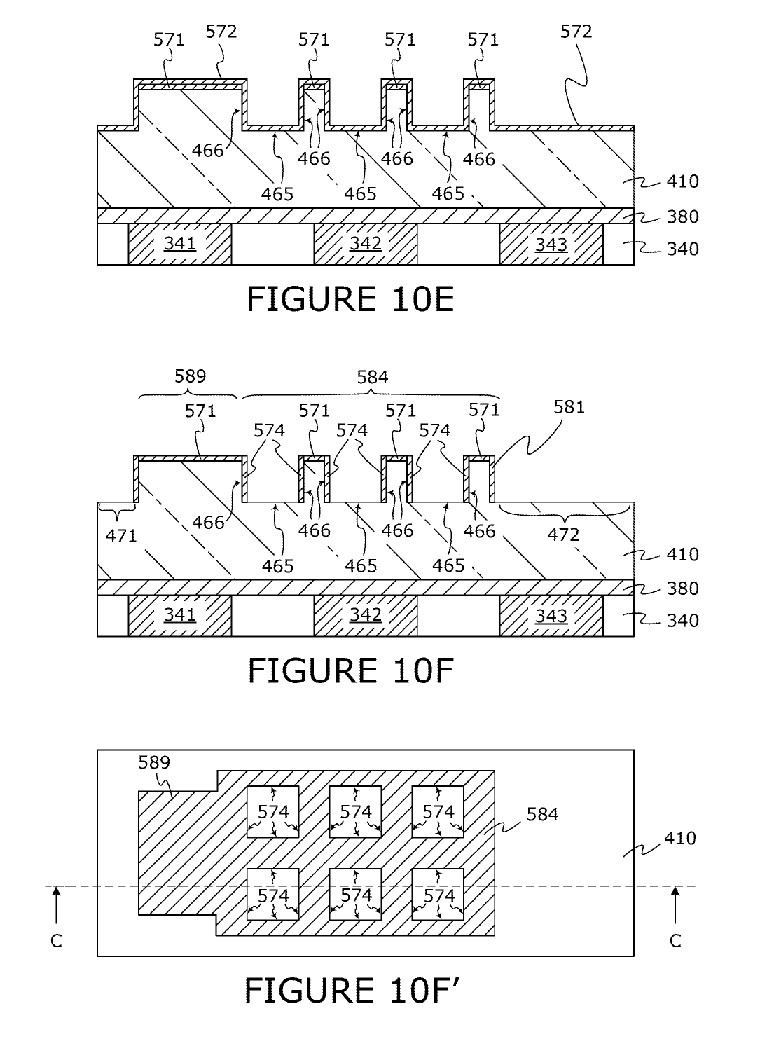

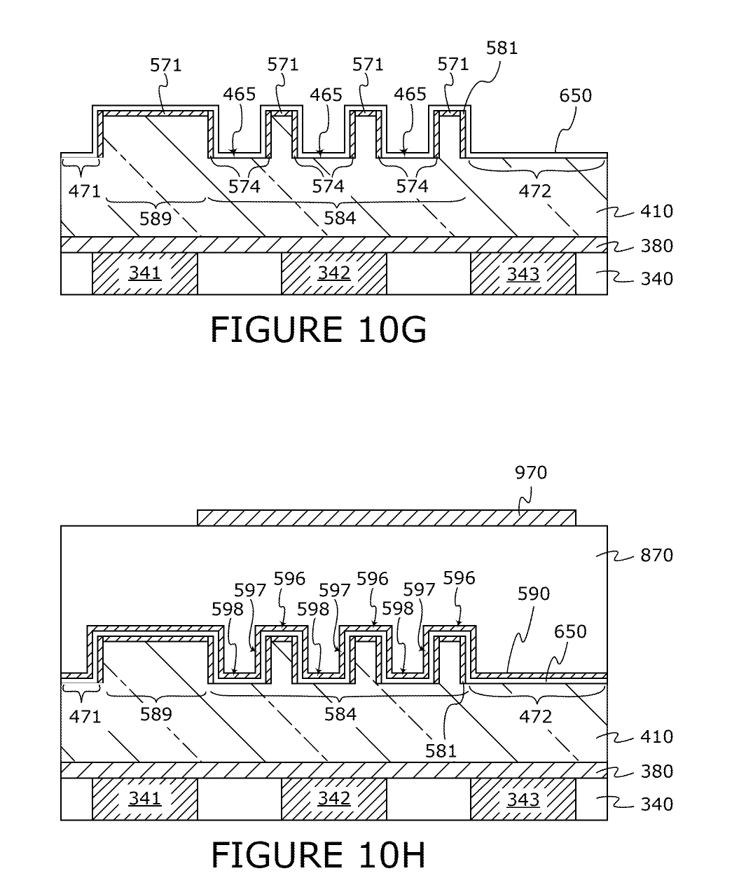

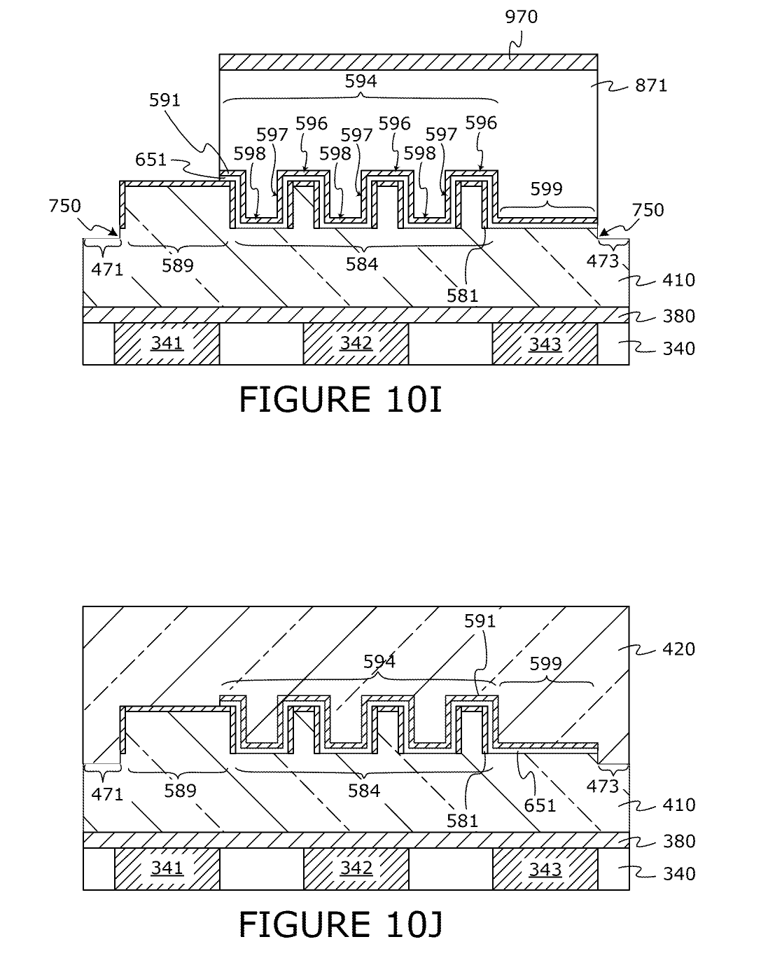

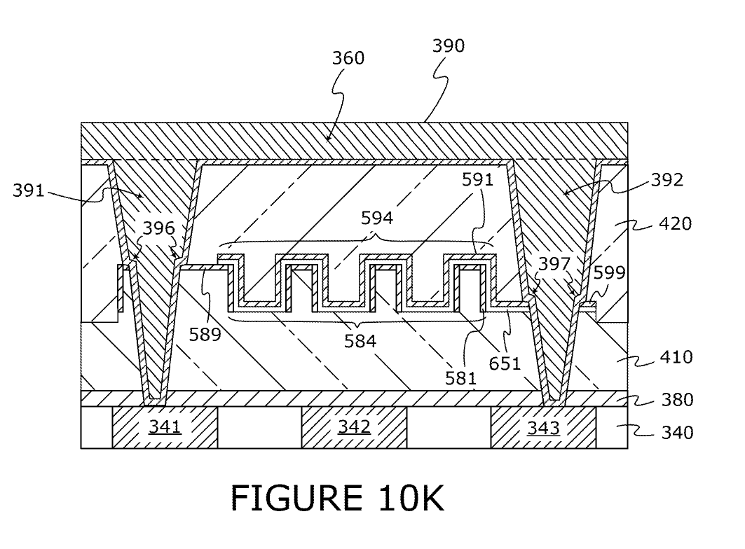

FIGS. 10A-10K illustrate a method of forming the semiconductor device having capacitor device as shown in FIG. 6 in accordance with one embodiment of the present invention. Similar to FIG. 8A, the fabrication of the semiconductor device begins by depositing a bottom passivation layer 410 above the topmost interlayer dielectric 340 as shown in FIG. 10A. Bottom passivation layer 410 has a top surface 460. For simplicity purposes, only the topmost interlayer dielectric 340 of the backend interconnect stack 300 is illustrated in FIGS. 10A-10K.

Next, a bottom electrode of the capacitor device is formed on the bottom passivation layer. In an embodiment of the present invention, the bottom electrode is formed by using a spacer-like process. The fabrication of the bottom electrode begins by blanket depositing a conductive layer 570 onto the top surface 460 of the bottom passivation layer 410 as shown in FIG. 10B. The conductive layer 570 is made from the same materials and techniques used in fabricating the conductive layer 510 in FIG. 8B, and hence will not be described in detail here. In one embodiment, a sacrificial material 860 is blanket deposited on the conductive layer 570. Sacrificial material 860 is made from the similar materials and techniques used for the sacrificial material 810 as described in relation to FIG. 8B.

A photoresist mask 960 is then formed on the sacrificial material 860. The photoresist mask 960 includes a plurality of openings 961 to define a waffle pattern on the top surface 460 of bottom passivation layer 410. FIG. 10B′ shows a top plan view of the photoresist mask 960 in FIG. 10B. In one embodiment, the photoresist mask 960 includes six openings 961 formed in a 2×3 arrangement as shown in FIG. 10B′. Even though FIG. 10B′ illustrates the photoresist mask 960 having six openings 961, it can be appreciated that the photoresist mask 960 may include greater or lesser than six openings 961. In one embodiment, the photoresist mask 960 comprises at least one opening 961. Viewing into line C-C in FIG. 10B′ shows the cross-sectional view of the photoresist mask 960 in FIG. 10B. The photoresist mask 960 is made from the same materials and techniques used in fabricating the photoresist mask 910 in FIG. 8B, and hence will not be described in detail here. In another embodiment, the photoresist mask 960 is formed directly onto the conductive layer 570 without any intermediate sacrificial material.

Subsequently, an etching process is performed in alignment to the photoresist mask 960 to form a waffle pattern on the top surface 460 of bottom passivation layer 410. Referring to FIG. 10C, the etching process removes portions of the bottom passivation layer 410 not covered by the photoresist mask 960 to define a waffle pattern comprising a top surface 461 having a plurality of recesses, each recess having sidewalls 466 extending from top surface 461 to a bottom surface 465. In particular, the plurality of recesses are formed by etching in alignment to the plurality of openings 961 of the photoresist mask 960.

Furthermore, the etching process also removes portions of the conductive layer 570 not covered by the photoresist mask 960 to form a perforated conductive layer 571 on the top surface 461. Also, the etching process removes any portions of the sacrificial material 860 not covered by the photoresist mask 960 so that only a remaining portion 861 of the sacrificial material is left on the perforated conductive layer 571.

The etching process utilizes well known dry-etch or wet-etch techniques. In one embodiment, the etching process uses an etchant chemistry that selectively removes portions of the sacrificial material 860, conductive layer 570 and bottom passivation layer 410 not covered by the photoresist mask 960.

After etching is complete, the photoresist mask 960 and the remaining portion 861 of sacrificial material are removed from the perforated conductive layer 571 as shown in FIG. 10D. The photoresist mask 960 can be removed by well known techniques, such as plasma ashing. An optional cleaning process can be performed on the perforated conductive layer 571 to remove any contaminants thereon.

Next, in FIG. 10E, another conductive layer 572 is blanket deposited onto the entire bottom passivation layer 410. In one embodiment, the conductive layer 572 is deposited conformally onto the perforated conductive layer 571, and onto the plurality of recesses of bottom passivation layer 410. In one embodiment, the conductive layer 572 is deposited with a smaller thickness than the conductive layer 570 or perforated conductive layer 571. For example, the conductive layer 572 has a thickness of about 10 to 20 nanometers and the conductive layer 570 or perforated conductive layer 571 has a thickness of about 35 nanometers. The conductive layer 572 is made from the same materials and techniques (e.g. CVD, PVD, ALD) used in fabricating the conductive layer 510 in FIG. 8B, and hence will not be described in detail here.

Next, in FIG. 10F, an etching process is performed on the conductive layer 572 to define the bottom electrode. In one embodiment, a blanket anisotropic etch is used to remove portions of the conductive layer 572 deposited on the bottom surfaces 465 of the plurality of recesses. In this case, portions 574 of the conductive layer 572 remain on the sidewalls 466 of the plurality of recesses after the anisotropic etch, wherein portions 574 are coupled to the perforated conductive layer 571. Portions 574 represent spacer-like features. For illustration purposes, portions 574 and perforated conductive layer 571 are illustrated as separate features in FIG. 10F. However, it can be appreciated that portions 574 and perforated conductive layer 571 form a single bottom electrode 581.

Bottom electrode 581 includes a waffle-shaped bottom plate 584 having a terminal region 589. The waffle-shaped bottom plate 584 comprises a plurality of lower recesses as represented by portions 574, wherein portions 574 are hereinafter referred to as sidewalls 574. Sidewalls 574 extend from perforated conductive layer 571, also referred herein as upper layer 571. FIG. 10F′ illustrates a top plan view of the bottom electrode 581, where the bottom electrode 581 comprises six recesses as represented by their sidewalls 574. However, it can be appreciated that the bottom electrode 581 can have greater or lesser than six recesses. In one embodiment, the bottom electrode 581 comprises at least one recess. Viewing into line C-C shows the cross-sectional view of the bottom electrode 581 in FIG. 10F.

Furthermore, the anisotropic etch also exposes regions 471, 472 of the bottom passivation layer 410, wherein exposed regions 471 is adjacent to terminal region 589, and wherein exposed region 472 is adjacent to the waffle-shaped bottom plate 584.

Next, a dielectric layer is formed on the bottom electrode 581. In an embodiment of the present invention, a dielectric layer 650 is blanket deposited onto the entire bottom electrode 581 as shown in FIG. 10G. Furthermore, the dielectric layer 650 is also deposited onto the exposed regions 471, 472 of the bottom passivation layer 410. In one embodiment, the dielectric layer 650 is deposited conformally onto the waffle-shaped bottom electrode 584 so that the dielectric layer 650 has a waffle shape. In particular, the dielectric layer 650 is deposited conformal to the upper layer 571, sidewalls 574 and bottom surfaces 465. The dielectric layer 650 is made from the same materials as the dielectric layer 611 described in relation to FIG. 2, and thus will not be discussed in detail here. In one embodiment, the dielectric layer 650 is deposited by well known methods such as but not limited to PVD, CVD or ALD.

Next, the top electrode of the capacitor device is formed on the dielectric layer. In an embodiment of the present invention, the fabrication of the top electrode begins by blanket depositing a conductive layer 590 onto the dielectric layer 650 as shown in FIG. 10H. In one embodiment, the conductive layer 590 is deposited conformally to the dielectric layer 650 so that the conductive layer 590 has a waffle shape comprising a plurality of upper recesses. Each upper recess comprises sidewalls 597 extending from an upper layer 596 to a lower layer 598. The conductive layer 590 is made from the same materials and techniques (e.g. CVD, PVD, ALD) used in fabricating the conductive layer 510 in FIG. 8B, and hence will not be described in detail here.

In one embodiment, a sacrificial material 870 is blanket deposited on the conductive layer 590. Sacrificial material 870 is made from the same materials and techniques used for the sacrificial material 810 as described in relation to FIG. 8B. A photoresist mask 970 is then formed on the sacrificial material 870 to define a portion of conductive layer 590 to form the top electrode. In one embodiment, the photoresist mask 970 is formed above the plurality of upper recesses of the conductive layer 590. The photoresist mask 970 is made from the same materials and techniques used in fabricating the photoresist mask 910 in FIG. 8B, and hence will not be described in detail here. In another embodiment, the photoresist mask 970 is formed directly on the conductive layer 590 without any intermediate sacrificial material.

Next, an etching process is performed in alignment to the photoresist mask 970 to form a top electrode from a desired portion of the conductive layer 590. In particular, the etching process removes any portions of the conductive layer 590 not covered by the photoresist mask 970 to form the top electrode 591 as shown in FIG. 10I. In one embodiment, a portion of the conductive layer 590 that is above the terminal region 589 of the bottom electrode 581 is removed during the etching process. In an embodiment of the present invention, the top electrode 591 comprises a waffle-shaped top plate 594 having a terminal region 599. Waffle-shaped top plate 594 includes the plurality of upper recesses, wherein each upper recess comprises sidewalls 597 extending from an upper layer 596 of top plate 594 to a lower layer 598.

In an embodiment of the present invention, the etching process further removes any portions of the dielectric layer 650 not covered by the photoresist mask 970. In this case, a portion 651 of the dielectric layer 650 remains between the waffle-shaped top plate 591 and the waffle-shaped bottom plate 581. Hereinafter, the portion 651 is referred to as dielectric layer 651. As a result, the terminal region 589 of the bottom electrode 581 is exposed. Furthermore, region 471 and region 473 of bottom passivation layer 410 are exposed by the etching process. Region 473 of the bottom passivation layer 410 is adjacent to the terminal region 599 of top electrode 591.

Furthermore, the etching process also removes any portions of the sacrificial material 870 not covered by the photoresist mask 970 so that only a remaining portion 871 of the sacrificial material 870 is left on the top electrode 591. The etching process uses well known dry-etch or wet-etch techniques. In one embodiment, the etching process uses an etchant chemistry that selectively removes portions of the sacrificial material 870 and conductive layer 590 not covered by the photoresist mask 970.

In one embodiment, the etching may cause an over-etch 750 at the exposed regions 471, 473 of bottom passivation layer 410. However, the bottom passivation layer 410 has sufficient thickness to prevent any defects resulting from the over-etch 750.

After etching is complete, both the photoresist mask 970 and the remaining portion 871 of sacrificial material are removed from the top electrode 591. The photoresist mask 970 can be removed by well known techniques, such as plasma ashing. An optional cleaning step can be performed on the top electrode 591 to remove any contaminants thereon.

Next, a top passivation layer 420 is deposited over the entire top electrode 591 as shown in FIG. 10J. In an embodiment of the present invention, the top passivation layer 420 is deposited over the entire top electrode 591 as well as the terminal region 589 of the bottom electrode 581. Furthermore, the top passivation layer 420 is also deposited onto the exposed regions 471, 473 of the bottom passivation layer 410. The top passivation layer 420 uses similar materials as the top passivation layer 420 described in relation to FIG. 2. The top passivation layer 420 can be formed by any well known methods, such as but not limited to PVD or CVD.

Next, in FIG. 10K, the first interconnect 391 and second interconnect 392 are formed by applying the methods previously described in relation to FIGS. 8H and 8I. Briefly, a first via and a second via (not shown) are formed in the bottom and top passivation layers 410, 420, which extend through the terminal regions 589, 599 respectively. Subsequently, an adhesion layer 360 is deposited onto the first via and second via before depositing the metal layer 390.

After depositing the metal layer 390, the portions of metal layer 390 deposited on top of the top passivation layer 420 can be patterned by well known lithography and etching techniques to form the first metal layer 393 and second metal layer 394 as shown in FIG. 6. The first and second solder bumps 398, 399 are then formed onto the first and second metal layers 393, 394.

As described above, the method in FIGS. 9A-9J uses three patterning steps or mask steps as shown by FIGS. 9B, 9E and 9G to form the capacitor device. However, the method described in relation to FIGS. 10A-10K uses two patterning steps or mask steps as shown in FIGS. 10B and 10I to form the capacitor device, which reduces one mask step.

Several embodiments of the invention have thus been described. However, those ordinarily skilled in the art will recognize that the invention is not limited to the embodiments described, but can be practiced with modification and alteration within the spirit and scope of the appended claims that follow.

We claim:

1. A semiconductor device comprising:
a substrate having a backend interconnect stack formed thereon, wherein the backend interconnect stack includes a topmost interlayer dielectric;
a bottom passivation layer formed above the topmost interlayer dielectric;
a top passivation layer formed on the bottom passivation layer; and
a capacitor device disposed between the bottom passivation layer and top passivation layer, the capacitor device comprising
a bottom electrode formed on the bottom passivation layer comprising a bottom plate having at least one lower ridge,
a top electrode formed above the bottom electrode comprising a top plate having at least one upper ridge, wherein the top plate is complementarily shaped to the bottom plate such that the upper ridge of the top plate is overlying the lower ridge of bottom plate, and
a dielectric layer disposed between the bottom electrode and the top electrode.

2. The semiconductor device of claim 1,
wherein the bottom plate includes a terminal region; and
wherein the top plate includes a terminal region.

3. The semiconductor device of claim 1,
wherein the lower ridge comprises
an upper layer, and
a first sidewall and a second sidewall extending from opposite sides of the upper layer; and
wherein the upper ridge comprises
an upper layer, and
a first sidewall and a second sidewall extending from opposite sides of the upper layer.

4. The semiconductor device of claim 3, wherein the upper layer, first sidewall, and second sidewalls of the upper and lower ridges have substantially equal thickness.

5. The semiconductor device of claim 1, further comprising:
a first interconnect coupling the terminal region of bottom electrode to a first metal layer in the topmost interlayer dielectric; and
a second interconnect coupling the terminal region of top electrode to a second metal layer in the topmost interlayer dielectric.

6. The semiconductor device of claim 5,
wherein the first interconnect includes a sidewall with a step adjacent to the terminal region of bottom electrode, and
wherein the second interconnect includes a sidewall with a step adjacent to the terminal region of top electrode.

7. The semiconductor device of claim 5, further comprising:
a first solder bump formed on top of the first interconnect; and
a second solder bump formed on top of the second interconnect, wherein the first and second solder bumps electrically couples the first and second interconnects to a package substrate or circuit board.

8. A semiconductor device comprising:
a substrate having a backend interconnect stack formed thereon, wherein the backend interconnect stack includes a topmost interlayer dielectric;
a bottom passivation layer formed above the topmost interlayer dielectric;
a top passivation layer formed on the bottom passivation layer; and
a capacitor device disposed between the bottom passivation layer and top passivation layer, the capacitor device comprising a bottom electrode formed on the bottom passivation layer comprising a bottom plate having at least one lower recess,
a top electrode formed above the bottom electrode comprising a top plate having at least one upper recess, wherein the top plate is complementarily shaped to the bottom plate such that the upper recess of the top plate is overlying the lower recess of bottom plate, and
a dielectric layer disposed between the bottom electrode and the top electrode.

9. The semiconductor device of claim 8,
wherein the bottom plate includes a terminal region; and
wherein the top plate includes a terminal region.

10. The semiconductor device of claim 8,
wherein the lower recess comprises sidewalls extending from an upper layer of the bottom plate; and
wherein the upper recess comprises sidewalls extending from an upper layer of the top plate to a lower layer.

11. The semiconductor device of claim 10, wherein the upper layer and sidewalls of bottom plate have substantially equal thickness as the upper layer, sidewalls and lower layer of top plate.

12. The semiconductor device of claim 9, further comprising:
a first interconnect coupling the terminal region of bottom electrode to a first metal layer in the topmost interlayer dielectric; and
a second interconnect coupling the terminal region of top electrode to a second metal layer in the topmost interlayer dielectric.

13. The semiconductor device of claim 12,
wherein the first interconnect includes a sidewall with a step adjacent to the terminal region of bottom electrode, and
wherein the second interconnect includes a sidewall with a step adjacent to the terminal region of top electrode.

14. The semiconductor device of claim 12, further comprising:
a first solder bump formed on top of the first interconnect; and
a second solder bump formed on top of the second interconnect, wherein the first and second solder bumps electrically couples the first and second interconnects to a package substrate or circuit board.

15. A method of forming a semiconductor device comprising:
providing a substrate having a backend interconnect stack formed thereon, wherein the backend interconnect stack includes a topmost interlayer dielectric;
depositing a bottom passivation layer above the topmost interlayer dielectric;
patterning the bottom passivation layer to form a fin thereon, the fin having a top surface, a first sidewall and a second sidewall, wherein the first sidewall and second sidewall extends from the top surface of fin to the top surface of bottom passivation layer;
forming a bottom electrode on the bottom passivation layer;
forming a dielectric layer on the bottom electrode;
forming a top electrode on the dielectric layer, wherein the top electrode and bottom electrode is able to store electrical energy between them; and
depositing a top passivation layer on the top electrode.

16. The method of claim 15, wherein patterning the bottom passivation layer to form a fin thereon comprises:
depositing a sacrificial material on the bottom passivation layer;
forming a photoresist mask on the sacrificial material, wherein the photoresist mask defines portions of the bottom passivation layer to be removed so as to form the fin; and
etching the bottom passivation layer in alignment with the photoresist mask to form the fin.

17. The method of claim 16, wherein forming the bottom electrode on the bottom passivation layer comprises:
conformally depositing a first conductive layer onto the fin and top surface of the bottom passivation layer; and
patterning the conductive layer to form the bottom electrode having a lower ridge.

18. The method of claim 17, wherein forming the dielectric layer on the bottom electrode comprises:
conformally depositing the dielectric layer onto the lower ridge of bottom electrode.

19. The method of claim 18, wherein forming the top electrode on the dielectric layer comprises:
conformally depositing a second conductive layer onto the dielectric layer; and
patterning the second conductive layer to form the top electrode having an upper ridge, wherein the top electrode is complementarily shaped to the bottom electrode such that the upper ridge of top electrode is overlying the lower ridge of bottom electrode.

20. A method of forming a semiconductor device comprising:
providing a substrate having a backend interconnect stack formed thereon, wherein the backend interconnect stack includes a topmost interlayer dielectric;
depositing a bottom passivation layer above the topmost interlayer dielectric;
forming a bottom electrode on the bottom passivation layer, comprises:
depositing a first conductive layer onto a top surface of bottom passivation layer;
patterning the first conductive layer and the bottom passivation layer to form a recess on the top surface of the bottom passivation layer, and to form a perforated first conductive layer on the top surface;
conformally depositing a second conductive layer onto the perforated first conductive layer and the recess of the bottom passivation layer; and
anisotropically etching the second conductive layer to form bottom electrode having a lower recess, the lower recess having sidewalls extending from the perforated first conductive layer;
forming a dielectric layer on the bottom electrode;
forming a top electrode on the dielectric layer, wherein the top electrode and bottom electrode is able to store electrical energy between them; and
depositing a top passivation layer on the top electrode.

21. The method of claim 20, wherein patterning the first conductive layer and the bottom passivation layer comprises:
depositing a sacrificial material onto the first conductive layer;
forming a photoresist mask on the sacrificial material, wherein the photoresist mask includes an opening to define the recess on the top surface of the bottom passivation layer;
etching the bottom passivation layer and first conductive layer in alignment with the photoresist mask to form recess on the top surface of the bottom passivation layer, and to form the perforated first conductive layer on the top surface.

22. The method of claim 20, wherein anisotropically etching the second conductive layer removes portions of the second conductive layer from the bottom surface of the recess so that remaining portions of the second conductive layer form sidewalls of the lower recess of bottom electrode.

23. The method of claim 20, wherein forming a top electrode on the dielectric layer comprises:
conformally depositing a third conductive layer onto the dielectric layer; and
patterning the third conductive layer to form the top electrode having an upper recess, wherein the top electrode is complementarily shaped to the bottom electrode such that the upper recess of top electrode is overlying the lower recess of bottom electrode.

24. The method of claim 20, further comprising
forming a first opening and a second opening in the bottom passivation layer and top passivation layer,
wherein the first opening extends through a terminal region of the bottom electrode, the first opening includes a sidewall having a step adjacent to the terminal region of the bottom electrode, and
wherein the second opening extends through a terminal region of the top electrode, the second opening includes a sidewall having a step adjacent to the terminal region of the top electrode.

25. The method of claim 24, wherein the first opening and second opening is formed by a dry-etching process that uses an etchant chemistry with a higher selectivity to the bottom passivation layer.

26. The method of claim 24, further comprising:
depositing a metal layer into the first opening and second opening to form a first interconnect in the first opening and form a second interconnect in the second opening,
wherein the first interconnect includes a sidewall with a step adjacent to the terminal region of bottom electrode, and
wherein the second interconnect includes a sidewall with a step adjacent to the terminal region of top electrode.
